(19) United States
(12) Patent Application Publication
(10) Pub. No.: US 2014/0203815 A1
(43) Pub. Date: Jul. 24, 2014

(54) WIRING FAULT DETECTION METHOD AND WIRING FAULT DETECTION APPARATUS

(71) Applicant: Masakazu Yanase, Osaka-shi (JP)

(72) Inventor: Masakazu Yanase, Osaka-shi (JP)

(73) Assignee: SHARP KABUSHIKI KAISHA, Osaka-shi, Osaka (JP)

(21) Appl. No.: 14/236,980

(22) PCT Filed: Sep. 10, 2012
(86) PCT No.: PCT/JP2012/073013

§ 371 Date: Feb. 4, 2014

(30) Foreign Application Priority Data
Sep. 12, 2011 (JP) 2011-198854

(51) Int. Cl. G01R 1/07

(52) U.S. Cl. CPC G01R 1/071
USPC 324/501

(57) ABSTRACT

A wiring fault detection method and apparatus capable of appropriately detecting a fault in the case of capturing an image of a panel a plurality of times using an infrared camera are provided.

The wiring fault detection method according to the present invention acquires correspondence between individual test regions and pads corresponding to the individual test regions. The wiring fault detection apparatus according to the present invention includes pad switching means for switching a pad to which power is to be supplied to a pad corresponding to each test region.

### TECHNICAL FIELD

The present invention relates to a wiring fault detection method and a wiring fault detection apparatus that are suitable for detecting a fault of a wiring line formed on a panel, such as a liquid crystal panel or a solar battery panel, and particularly relates to a wiring fault detection method and a wiring fault detection apparatus directed to a large panel.

### BACKGROUND ART

A process for manufacturing a liquid crystal panel, which is an example of a semiconductor substrate, roughly includes an array (TFT) step, a cell (liquid crystal) step, and a module step. In the array step among these steps, gate electrodes, a semiconductor film, source/drain electrodes, a protection film, and transparent electrodes are formed on a transparent substrate, and then array detection is performed, so that the presence/absence of a short circuit of wiring, such as an electrode or a wiring line, is detected.

Normally, in array detection, such a fault is specified by causing a probe to be in contact with an end portion of a wiring line and measuring an electric resistance at both ends of the wiring line or an electric resistance and electric capacitance between wiring lines adjacent to each other. However, even if the presence/absence of a fault in a wiring portion can be detected through array detection, it is not easy to specify the position of the fault.

For example, as a method for addressing the above-described problem and specifying the position of a fault, infrared detection is available in which a voltage is applied to a leak fault substrate to generate heat, and the position of a fault is specified using an image that is captured by an infrared camera and that indicates the temperature of the surface of the leak fault substrate.

PTL 1 relates to an infrared test in which a short-circuit fault of a substrate is detected using infrared images, and a liquid crystal panel on a semiconductor substrate (leak fault substrate) as a target to be tested is divided into a plurality of regions. In this fault detection method, after a voltage is applied to the entire liquid crystal panel, the intensities (temperatures) of infrared images of the liquid crystal panel before and after the voltage is applied are measured for individual regions obtained through division, and heat generation is made apparent to detect a fault.

### CITATION LIST

### Patent Literature

PTL 1: Japanese Unexamined Patent Application Publication No. 6-207914 (publication date: Jul. 26, 1994)

### SUMMARY OF INVENTION

### Technical Problem

However, in a case where the technique described in PTL 1 is used, a voltage is applied to the entire liquid crystal panel on a semiconductor substrate (leak fault substrate), and thus heat is generated in the entire panel, and heat is generated in a region where an infrared image has not been captured. Thus, in the case of performing, after performing an infrared test on a certain test region obtained through division, an infrared test on the next test region obtained through division, heat remains in the next test region which is obtained through division and to which voltage has not been applied, an appropriate infrared image before voltage is applied is not obtained, and a difference in intensity (a difference in temperature) that is necessary for detecting a fault is not generated in infrared images captured before and after voltage application. That is, if this related art is used in the case of dividing an entire liquid crystal panel into a plurality of test regions and capturing an infrared image of the liquid crystal panel a plurality of times, it is difficult to detect a fault.

### Solution to Problem

The present invention has been made in view of the above-described problem, and an object of the invention is to provide a wiring fault detection method and a wiring fault detection apparatus that are capable of appropriately detecting a fault in the case of dividing a liquid crystal panel on a semiconductor substrate into a plurality of test regions and capturing an infrared image of the liquid crystal panel on the semiconductor substrate a plurality of times.

To solve the above-described problem, a wiring fault detection method according to the present invention is a wiring fault detection method for detecting a fault of a wiring line by capturing, using an infrared camera, an image of a panel including a plurality of pads and wiring lines, including:

a storage step of storing correspondence data in a data storage unit, the correspondence data representing correspondence between a plurality of test regions, which are obtained by dividing the panel in accordance with a region of an image capturing field of the infrared camera, and pads corresponding to the individual test regions among the plurality of pads;

a pad switching step of changing relative positions of the panel and the infrared camera, and switching a pad to which power is to be supplied, on the basis of a position of the region of the image capturing field of the infrared camera and the correspondence data stored in the data storage unit;

a voltage application step of applying, via the pad switched in the pad switching step, a predetermined voltage to the wiring line corresponding to the pad; and

a fault detection step of detecting a fault of the wiring line by capturing, using the infrared camera, an image of a test region including the wiring line to which the voltage is applied in the voltage application step.

According to the above-described configuration, in the case of capturing, using the infrared camera, an image of a panel (leak fault substrate) that is a target of wiring fault detection and has a region larger than the region of the image capturing field of the infrared camera, by changing the relative positions of the infrared camera and the panel, heat can be generated by applying a voltage to only each test region of the panel included in the region of the image capturing field of the infrared camera in accordance with change in the relative positions.

Further, since a voltage is applied to only a certain test region to generate heat and an image of the certain test region is captured, heat generation that causes inconvenience to an infrared test does not occur in a test region which is different from the certain test region and in which an infrared test has not been performed in the panel.

Thus, even in the case of detecting a wiring fault of a relatively large panel (for example, a 60-inch liquid crystal panel) that is larger than a single region of an image capturing field by utilizing heat generation caused by voltage application, an increase in temperature required to detect a fault can be achieved in each test region, and a fault can be appropriately detected.

Preferably, according to an embodiment of the wiring fault detection method according to the present invention, in addition to the above-described configuration, a preliminary step of the storage step includes a correspondence creation step of creating the correspondence data by dividing the panel into a plurality of test regions in accordance with the region of the image capturing field of the infrared camera, determining pads corresponding to the individual test regions among the plurality of pads, and associating the test regions with the pads corresponding to the test regions.

Since the correspondence creation step is included, in the case of detecting a wiring fault of a panel including a pad whose correspondence with respect to the infrared camera is not stored in the data storage unit in advance, a plurality of test regions obtained by dividing the panel can be associated with the pads corresponding to the individual test regions.

Thus, the wiring fault detection apparatus is not an apparatus applicable to only panels of a determined size or an apparatus applicable to only pads corresponding to a determined range of image capturing field and test region, and correspondence data can be created every time a test is performed or if necessary, and a favorable divisional detection can be realized.

Preferably, according to an embodiment of the wiring fault detection method according to the present invention, in addition to the above-described configuration, a preliminary step of the correspondence creation step includes

a number-of-test-regions judgment step of judging whether or not the panel is to be divided into a plurality of test regions in accordance with a size of the panel and a size of the region of the image capturing field of the infrared camera, and

a test region determination step of determining, in a case where it is judged in the number-of-test-regions judgment step that the panel is to be divided into a plurality of test regions, a size of each of the test regions.

Since the number-of-test-regions judgment step and the test region determination step are included, in the case of detecting a wiring fault of a liquid crystal panel in which the size of each test region is not determined, the size of each test region can be determined on the basis of the size of the liquid crystal panel and the size of the region of the image capturing field of the infrared camera.

Preferably, according to an embodiment of the wiring fault detection apparatus according to the present invention, in addition to the above-described configuration, in the pad switching step, a pad to which power is to be supplied is switched to a pad corresponding to a test region in accordance with the position of the region of the image capturing field of the infrared camera, by switching a probe pin that is to be connected to a corresponding one of the pads to supply power to a probe pin for applying a voltage in the voltage application step.

Since the pad switching step is included, power is supplied to, via a corresponding probe, only a pad corresponding to each test region of the liquid crystal panel included in the region of the image capturing field of the infrared camera, and thereby heat can be generated only in the test region.

To solve the above-described problem, a wiring fault detection apparatus according to the present invention is a wiring fault detection apparatus for detecting a fault of a wiring line by capturing, using an infrared camera, an image of a panel including a plurality of pads and wiring lines, including:

the infrared camera;

a data storage unit for storing correspondence data, the correspondence data representing correspondence between a plurality of test regions, which are obtained by dividing the panel in accordance with a region of an image capturing field of the infrared camera, and pads corresponding to the individual test regions among the plurality of pads;

movement means for changing relative positions of the panel and the infrared camera;

pad switching means for switching a pad to which power is to be supplied, on the basis of a position of the region of the image capturing field of the infrared camera whose relative position is moved by the movement means, and the correspondence data stored in the data storage unit;

voltage application means for applying, via the pad switched by the pad switching means, a predetermined voltage to the wiring line corresponding to the pad; and

fault detection means for detecting a fault of the wiring line by capturing, using the infrared camera, an image of a test region including the wiring line to which the voltage is applied by the voltage application means,

wherein the pad switching means and the fault detection means are provided in a control unit.

According to the above-described configuration, in the case of capturing, using the infrared camera, an image of a panel (leak fault substrate) that is a target of wiring fault detection and has a region larger than the region of the image capturing field of the infrared camera, by changing the relative positions of the infrared camera and the panel, heat can be generated by applying a voltage to only each test region of the panel included in the region of the image capturing field of the infrared camera in accordance with change in the relative positions.

Further, since a voltage is applied to only a certain test region to generate heat and an image of the certain test region is captured, heat generation that causes inconvenience to an infrared test does not occur in a test region which is different from the certain test region and in which an infrared test has not been performed in the panel.

Thus, even in the case of detecting a wiring fault of a relatively large panel (for example, a 60-inch liquid crystal panel) that is larger than a single region of an image capturing field by utilizing heat generation caused by voltage application, an increase in temperature required to detect a fault can be achieved in each test region, and a fault can be appropriately detected.

Preferably, according to an embodiment of the wiring fault detection apparatus according to the present invention, in addition to the above-described configuration, the wiring fault detection apparatus further includes

a correspondence creation unit for creating the correspondence data by dividing the panel into a plurality of test regions in accordance with the region of the image capturing field of the infrared camera, determining pads corresponding to the individual test regions among the plurality of pads, and associating the test regions with the pads corresponding to the test regions,

wherein the data storage unit stores the correspondence data created by the correspondence creation unit, and

wherein the correspondence creation unit is provided in the control unit.

Since the correspondence creation means is included, in the case of detecting a wiring fault of a panel including a pad whose correspondence with respect to the infrared camera is not stored in the data storage unit in advance, a plurality of test regions obtained by dividing the panel can be associated with the pads corresponding to the individual test regions.

Thus, the wiring fault detection apparatus is not an apparatus applicable to only panels of a determined size or an apparatus applicable to only pads corresponding to a determined range of image capturing field and test region, and correspondence data can be created every time a test is performed or if necessary, and a favorable divisional detection can be realized.

Preferably, according to an embodiment of the wiring fault detection apparatus according to the present invention, in addition to the above-described configuration, the correspondence creation unit includes

number-of-test-regions judgment means for judging whether or not the panel is to be divided into a plurality of test regions in accordance with a size of the panel and a size of the region of the image capturing field of the infrared camera, and

test region determination means for determining, in a case where it is judged by the number-of-test-regions judgment means that the panel is to be divided into a plurality of test regions, a size of each of the test regions.

Since the number-of-test-regions judgment means and the test region determination means are included, in the case of detecting a wiring fault of a liquid crystal panel in which the size of each test region is not determined, the size of each test region can be determined on the basis of the size of the liquid crystal panel and the size of the region of the image capturing field of the infrared camera.

Preferably, according to an embodiment of the wiring fault detection apparatus according to the present invention, in addition to the above-described configuration, the wiring fault detection apparatus further includes

a probe pin that is to be connected to a corresponding one of the pads to supply power,

wherein the pad switching means switches a pad to which power is to be supplied to a pad corresponding to a test region in accordance with the position of the region of the image capturing field of the infrared camera, by performing switching to the probe pin for applying a voltage using the voltage application means.

Since the pad switching means is included, power is supplied to, via a corresponding probe pin, only a pad corresponding to each test region of the liquid crystal panel included in the region of the image capturing field of the infrared camera, and thereby heat can be generated only in the test region.

### Advantageous Effects of Invention

As described above, with the wiring fault detection method and wiring fault detection apparatus for a liquid crystal panel according to the present invention, heat is generated by applying a voltage to only each test region of the liquid crystal panel included in the region of the image capturing field of an infrared camera, and thus excessive heat generation in the liquid crystal panel does not occur in the other test regions where an infrared test for wiring fault detection is not performed. That is, in the other test regions where an infrared test for wiring fault detection is not performed, an excessive increase in the temperature of the liquid crystal panel can be prevented. Accordingly, even if power is immediately supplied to pads of the liquid crystal panel to generate heat in the liquid crystal panel in the case of performing an infrared test for wiring fault detection in the next test region of the liquid crystal panel, an increase in temperature required to detect a fault can be achieved, and a fault can be appropriately detected.

### BRIEF DESCRIPTION OF DRAWINGS

FIG. 1 includes a block diagram illustrating the configuration of an embodiment of a wiring fault detection apparatus according to the present invention, and a perspective view illustrating the configuration of a mother substrate provided with liquid crystal panels in which a fault is detected by the apparatus.

FIG. 2 is a perspective view illustrating the configuration of an embodiment of the wiring fault detection apparatus according to the present invention.

FIG. 3 includes plan views of a liquid crystal panel in which a fault is detected by the wiring fault detection apparatus according to the present invention, and a probe provided in the apparatus.

FIG. 4 is a flowchart illustrating a wiring fault detection method according to an embodiment of the present invention.

FIG. 5 includes schematic diagrams illustrating faults in a pixel portion according to the present invention.

FIG. 6 is a diagram illustrating an overview of a wiring fault detection method according to an embodiment of the present invention.

FIG. 7 is a flowchart illustrating a wiring fault detection method according to another embodiment of the present invention.

FIG. 8 is a schematic diagram of a liquid crystal panel according to an embodiment of the present invention.

FIG. 9 is a schematic diagram of a liquid crystal panel according to another embodiment of the present invention.

FIG. 10 is a schematic diagram illustrating a short-circuit path used in the present invention.

### DESCRIPTION OF EMBODIMENTS

### First Embodiment

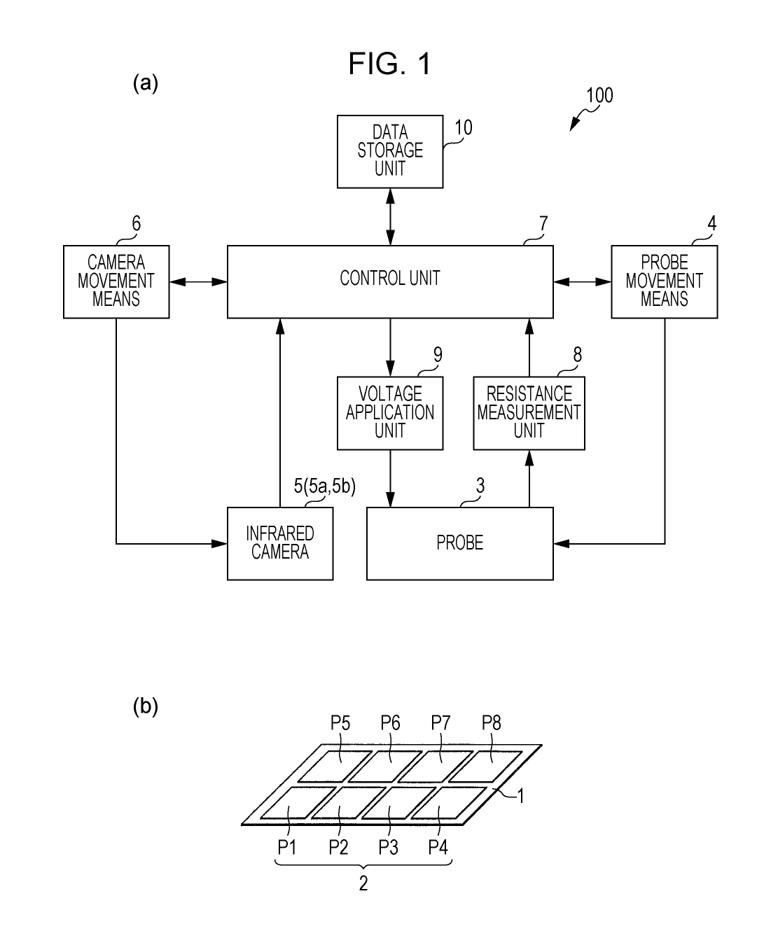

An embodiment of a wiring fault detection apparatus and a wiring fault detection method according to the present invention will be described with reference to FIGS. 1 to 5 and FIG. 8.

### (Configuration of Wiring Fault Detection Apparatus)

Part (a) of FIG. 1 is a block diagram illustrating the configuration of a wiring fault detection apparatus 100 according to this embodiment, and part (b) of FIG. 1 is a perspective view of a mother substrate 1, which is a target in which a wiring fault is to be detected using the wiring fault detection apparatus 100.

The wiring fault detection apparatus 100 is capable of detecting a fault of a wiring line and so forth in a plurality of liquid crystal panels 2 (panels) formed on the mother substrate 1 illustrated in part (b) of FIG. 1. As each of the liquid crystal panels 2, a relatively large panel of about 60 inches may be applied.

The wiring fault detection apparatus 100 includes, as illustrated in part (a) of FIG. 1, a probe 3 to be electrically connected to the liquid crystal panels 2, and probe movement means 4 for moving the probe 3 onto the individual liquid crystal panels 2. Also, the wiring fault detection apparatus 100 includes an infrared camera 5 for capturing an infrared image, and camera movement means 6 for moving the infrared camera 5 above the liquid crystal panels 2. Further, the wiring fault detection apparatus 100 includes a control unit 7 for controlling the probe movement means 4 and the camera movement means 6 (pad switching means and fault detection means).

A resistance measurement unit 8 for measuring a resistance between wiring lines of the liquid crystal panels 2, and a voltage application unit 9 (voltage application means) for applying a voltage between wiring lines of the liquid crystal panels 2 are connected to the probe 3. The resistance measurement unit 8 and the voltage application unit 9 are controlled by the control unit 7.

The control unit 7 includes a correspondence acquisition unit (not illustrated) for acquiring a relationship between individual test regions on the liquid crystal panels 2 and pads corresponding thereto (described below), and is connected to a data storage unit 10 that stores resistance values between wiring lines and image data.

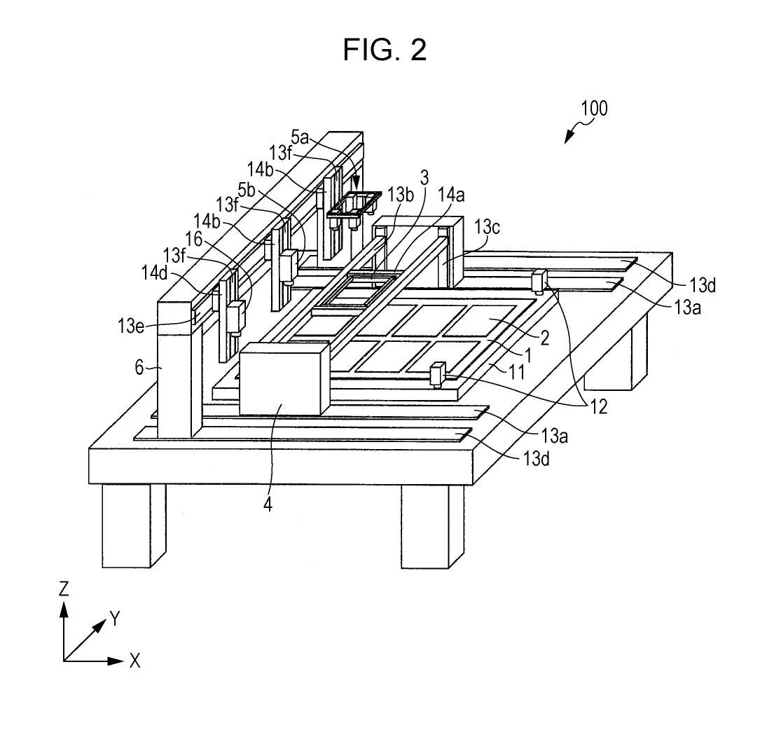

FIG. 2 is a perspective view illustrating the configuration of the wiring fault detection apparatus 100 according to this embodiment. As illustrated in FIG. 2, the wiring fault detection apparatus 100 includes an alignment stage 11 disposed on a base plate, and is configured so that the mother substrate 1 can be disposed on the alignment stage 11. The alignment stage 11 on which the mother substrate 1 is disposed is aligned in parallel with the X and Y coordinate axes of the probe movement means 4 and the camera movement means 6. In this case, to align the alignment stage 11, optical cameras 12 that are provided above the alignment stage 11 and are used to check the position of the mother substrate 1 are used.

The probe movement means 4 is slidably disposed on guide rails 13a that are disposed on the outer sides of the alignment stage 11. Also, guide rails 13b and 13c are disposed on the main body side of the probe movement means 4, and a mount portion 14a is disposed so as to be movable in the individual coordinate directions of X, Y, and Z along these guide rails 13. The probe 3 compatible with the liquid crystal panels 2 is mounted on the mount portion 14a.

The camera movement means 6 is slidably disposed on guide rails 13d that are disposed on the outer sides of the probe movement means 4. Also, guide rails 13e and 13f are disposed on the main body of the camera movement means 6. Three mount portions 14b, 14c, and 14d are capable of separately moving in the individual coordinate directions of X, Y, and Z along these guide rails 13.

In this embodiment, the infrared camera 5 provided in the wiring fault detection apparatus 100 includes two types of cameras. One is an infrared camera 5a for macro measurement, and the other is an infrared camera 5b for micro measurement.

The infrared camera 5a for macro measurement is mounted on the mount portion 14c of the wiring fault detection apparatus 100, the infrared camera 5b for micro measurement is mounted on the mount portion 14b, and an optical camera 16 is mounted on the mount portion 14d.

The infrared camera 5a for macro measurement is an infrared camera that has a field of view of about 520×405 mm and that is capable of performing macro measurement. To increase the field of view, the infrared camera 5a for macro measurement is configured by combining four infrared cameras. That is, the field of view of each infrared camera for macro measurement is about one-ninth of the mother substrate 1.

The infrared camera 5b for micro measurement is an infrared camera that has a small field of view of about 16×12 mm and that is capable of performing micro measurement in which high-resolution image capturing can be performed.

Additionally, a laser irradiation device for correcting a faulty portion can be mounted on the camera movement means 6 by adding a mount portion. In a case where the laser irradiation device is mounted, the position of a faulty portion can be specified and then the fault can be corrected by irradiating the faulty portion with laser light in a sequential manner.

The probe movement means 4 and the camera movement means 6 are disposed on the different guide rails 13a and 13d, and thus can be moved in the X coordinate direction above the alignment stage 11 without interfering with each other. Accordingly, the infrared cameras 5a and 5b and the optical camera 16 can be moved to a position above a liquid crystal panel 2 in a state where the probe 3 is in contact with the liquid crystal panel 2.

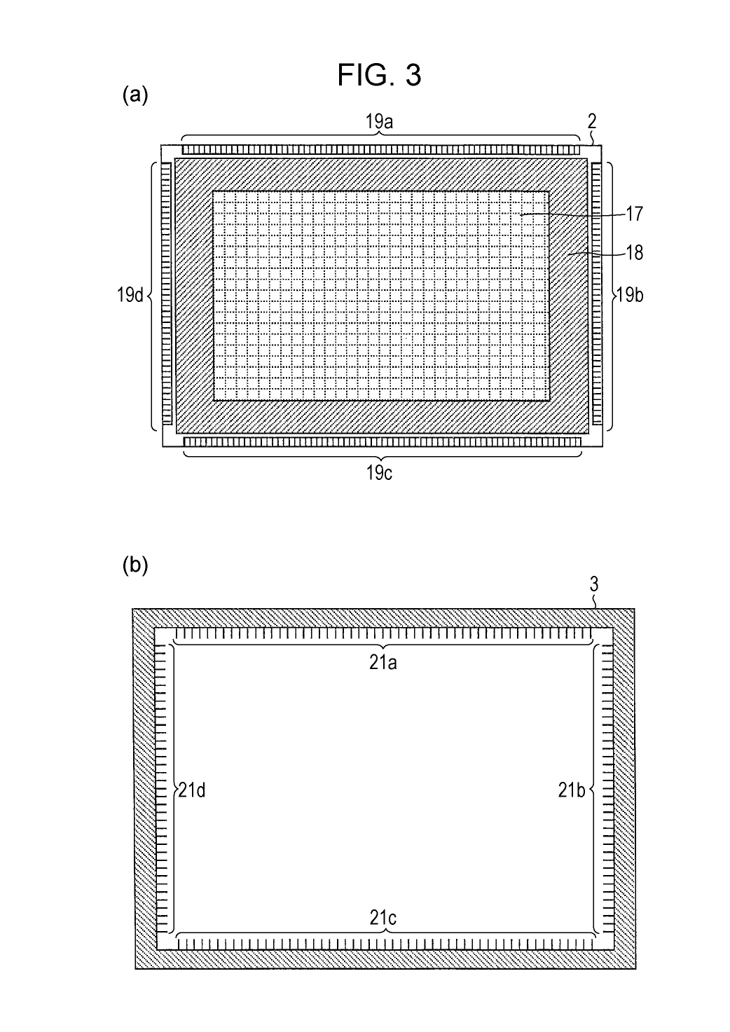

Part (a) of FIG. 3 is a plan view of one liquid crystal panel 2 among the plurality of liquid crystal panels 2 formed on the mother substrate 1. As illustrated in part (a) of FIG. 3, a pixel portion 17 in which TFTs are formed at individual intersections where scanning lines and signal lines cross each other, and a peripheral circuit portion 18 connected to the scanning lines and the signal lines are formed on each liquid crystal panel 2. Pads 19a to 19d are disposed at edge portions of the liquid crystal panel 2. The pads 19a to 19d are connected to wiring lines of the pixel portion 17 or the peripheral circuit portion 18. The pads 19 are not limited to those disposed in four directions (19a to 19d) illustrated in part (a) of FIG. 3, and may be those disposed in three directions (for example, 19a, 19b, and 19d).

Part (b) of FIG. 3 is a plan view of the probe 3 (voltage application means) that is to be electrically connected to the pads 19a to 19d disposed on the liquid crystal panel 2. The probe 3 has a frame shape, the size of which is almost the same as that of the liquid crystal panel 2 illustrated in part (a) of FIG. 3, and includes probe pins 21a to 21d at the positions corresponding to the pads 19a to 19d on the liquid crystal panel 2.

Regarding the probe pins 21a to 21d, the probe pins 21 can be individually connected to the resistance measurement unit 8 and the voltage application unit 9 illustrated in part (a) of FIG. 1 via a relay ON/OFF switch (not illustrated). Thus, in the probe 3, a plurality of wiring lines leading to the pads 19a to 19d can be selectively connected, or a plurality of wiring lines can be collectively connected.

As described above, the probe 3 has a shape of a frame, the size of which is almost the same as that of the liquid crystal panel 2. Thus, in the case of adjusting the positions of the pads 19a to 19d and the probe pins 21a to 21d, the positions can be checked using the optical camera 16 from the inner side of the frame of the probe 3.

The wiring fault detection apparatus 100 according to this embodiment includes the probe 3 and the resistance measurement unit 8 connected to the probe 3, and is capable of measuring a resistance value between adjacent wiring lines described below, by electrically connecting the probe 3 to the liquid crystal panel 2.

The wiring fault detection apparatus 100 according to this embodiment also includes the probe 3, the voltage application unit 9 connected to the probe 3, and the infrared camera 5. Before and after applying a voltage to wiring lines or between wiring lines of the liquid crystal panel 2 via the probe 3, the wiring fault detection apparatus 100 measures the temperature of the liquid crystal panel 2 by using the infrared camera 5.

The wiring fault detection apparatus 100 having the above-described configuration according to this embodiment is capable of implementing fault detection through image capturing, even in a case where the size of the liquid crystal panel 2 is large, for example, 60 inches as described above, compared with the size of the range of the image capturing field of the infrared camera 5. Although the details will be described below, the wiring fault detection apparatus 100 is capable of implementing fault detection because the wiring fault detection apparatus 100 performs fault detection on the entire region of the liquid crystal panel 2 while moving the infrared camera 5, by dividing the liquid crystal panel 2 into a plurality of test regions in accordance with the range of the image capturing field of the infrared camera 5. In particular, it is characteristic to the present invention that, when heat generation is caused by voltage application in a certain test region (that is, a certain image capturing region), heat generation is suppressed as much as possible in a region where the test has not been performed. Accordingly, when the infrared camera 5 moves and a new test region becomes a test target, accurate heat generation data can be acquired from the test region, and accordingly accurate fault detection can be performed.

Hereinafter, a detailed description will be given of fault detection that is performed using the wiring fault detection apparatus 100 according to this embodiment.

In particular, in the wiring fault detection apparatus 100 according to this embodiment, a resistance test and an infrared test can be performed by the single apparatus.

(Wiring Fault Detection Method)

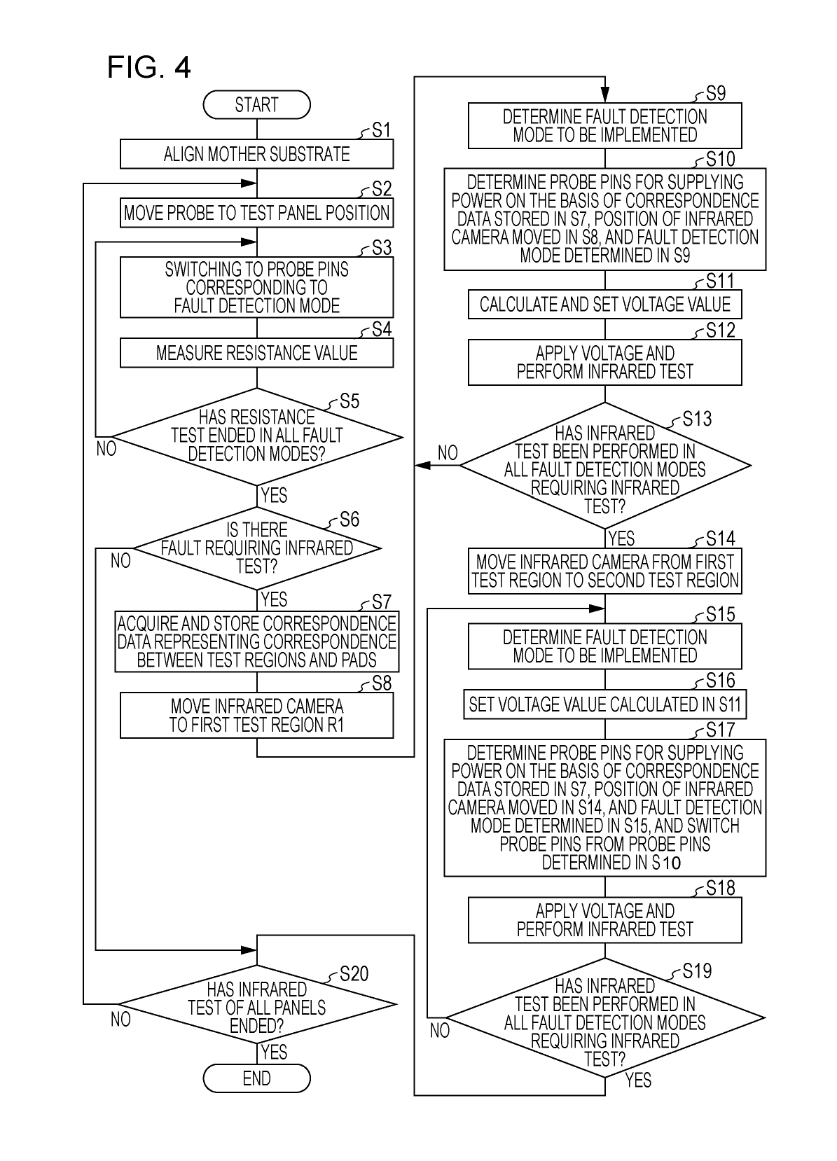

FIG. 4 is a flowchart of a wiring fault detection method using the wiring fault detection apparatus 100 according to this embodiment.

The wiring fault detection method according to this embodiment includes:

(i) a storage step of storing correspondence data in a data storage unit, the correspondence data representing correspondence between a plurality of test region, which are obtained by dividing a liquid crystal panel 2 in accordance with a region of an image capturing field of an infrared camera, and pads corresponding to the individual test regions;

(ii) a pad switching step of changing relative positions of the panel and the infrared camera, and switching a pad 19 to which power is to be supplied to a pad 19 corresponding to the test region R in accordance with a position of the region of the image capturing field of the infrared camera on the basis of the correspondence data stored in the storage unit;

(iii) a voltage application step of supplying power to the pad 19 switched in the pad switching step and applying a predetermined voltage to a wiring line corresponding to the pad 19; and

(iv) a fault detection method of detecting a fault by capturing, using the infrared camera 5, an image of a test region to which the voltage is applied in the voltage application step.

In the wiring fault detection method according to this embodiment, wiring fault detection is sequentially performed on the plurality of liquid crystal panels 2 formed on the mother substrate 1 illustrated in part (b) of FIG. 1, in steps S1 to S20.

Hereinafter, individual steps S1 to S20 will be described.

In step S1, the mother substrate 1 is placed on the alignment stage 11 of the wiring fault detection apparatus 100 illustrated in FIG. 2, and the mother substrate 1 is aligned so as to be parallel with the X and Y coordinate axes.

In step S2, the probe 3 is moved by the probe movement means 4 illustrated in FIG. 2 to a position above a certain liquid crystal panel 2 on the mother substrate 1 that is aligned in step S1, and the probe pins 21a to 21d on the upper, lower, right, and left sides come into contact with the pads 19a to 19d on the upper, lower, right, and left sides of the liquid crystal panel 2.

In step S3, after step S2, a portion between wiring lines as a target of a resistance test is selected in accordance with detection modes for various types of fault, and switching of the probe pins 21 to be brought into conduction is performed.

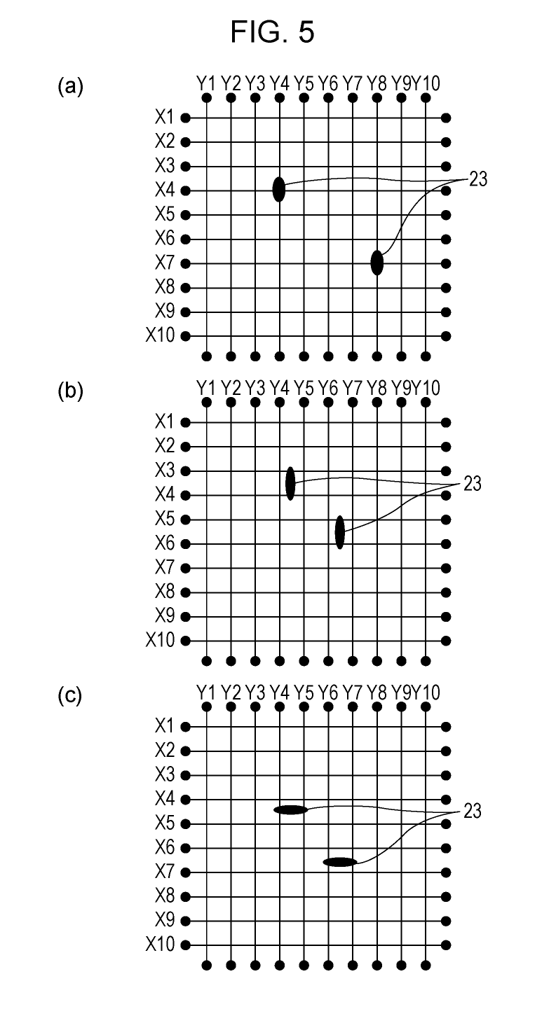

Now, detection modes for various types of fault will be described with reference to parts (a) to (c) of FIG. 5. In parts (a) to (c) of FIG. 5, the positions of faulty portions 23 (wiring short-circuit portions) generated in the pixel portion 17 are schematically illustrated as an example.

Part (a) of FIG. 5 illustrates faulty portions 23 in which wiring lines X and wiring lines Y are short-circuited at intersection portions in the liquid crystal panel where wiring lines X and wiring lines Y extend in the horizontal and vertical directions to intersect each other, for example, like scanning lines and signal lines. The probe pins 21 to be brought into conduction are switched to a pair of probe pins 21a on the upper side and probe pins 21d on the left side or a pair of probe pins 21b on the right side and probe pins 21c on the lower side illustrated in part (b) of FIG. 3, and resistance values between wiring lines are measured regarding wiring lines X1 to X10 and wiring lines Y1 to Y10 illustrated in part (a) of FIG. 5 in a one-to-one relationship. Accordingly, the presence/absence of the faulty portions 23 can be specified. Hereinafter, the fault detection mode in which fault detection is performed by applying a voltage between a wiring line X and a wiring line Y will be referred to as a “fault detection mode A”.

Part (b) of FIG. 5 illustrates faulty portions 23 in which wiring lines X adjacent to each other, for example, a scanning line and an auxiliary capacitance line, are short-circuited. In this case, the wiring line having such a faulty portion 23 can be specified by switching the probe pins 21 to be brought into conduction illustrated in part (b) of FIG. 3 to a pair of an odd-numbered pin of the probe pins 21b on the right side and an even-numbered pin of the probe pins 21d on the left side and by measuring the resistance values between wiring lines adjacent to each other among the wiring lines X1 to X10. Hereinafter, the fault detection mode in which fault detection is performed by applying a voltage between a wiring line X and a wiring line X will be referred to as a “fault detection mode B”.

Part (c) of FIG. 5 illustrates faulty portions 23 in which wiring lines Y adjacent to each other, for example, a scanning line and an auxiliary capacitance line, are short-circuited. In this case, the wiring line having such a faulty portion 23 can be specified by switching the probe pins 21 to be brought into conduction illustrated in part (b) of FIG. 3 to a pair of probe pins adjacent to each other among the probe pins 21a on the upper side (a pair of an odd-numbered probe pin 21a and an even-numbered probe pin 21a adjacent thereto) or a pair of probe pins adjacent to each other among the probe pins 21c on the lower side (a pair of an odd-numbered probe pin 21c and an even-numbered probe pin 21c adjacent thereto), and by measuring the resistance values between wiring lines adjacent to each other among the wiring lines Y1 to Y10. Hereinafter, the fault detection mode in which fault detection is performed by applying a voltage between a wiring line Y and a wiring line Y will be referred to as a “fault detection mode C”.

In step S4, the probe pins 21 switched in step S3 are brought into conduction, and the resistance value between selected wiring lines is measured and acquired. The acquired resistance value is stored in the data storage unit 10, together with information about the selected wiring lines.

In step S5, it is judged whether or not measurement of a resistance value has ended in all the fault detection modes A, B, and C. For example, it is assumed that measurement of a resistance value is performed in the order of the fault detection modes A, B, and C. In a case where only measurement of a resistance value in the fault detection mode A has ended, the process returns to step S3, in which the probe pins 21 are switched to those for the fault detection mode B, and measurement of a resistance value is performed in the following step S4. In a case where measurement of a resistance value in the fault detection modes A and B has ended, the process returns to step S3, in which the probe pins are switched to those for the fault detection mode C, and measurement of a resistance value is performed in the following step S4. In a case where measurement of a resistance value in all the fault detection modes A, B, and C has ended, the process proceeds to the following step S6.

In step S6, it is judged whether or not a fault requiring an infrared test exists in the liquid crystal panel 2 under the test.

First, the resistance value acquired in step S4 is compared with a resistance test threshold stored in the data storage unit 10 in advance. Here, in a case where the resistance value acquired in step S4 is larger than the resistance test threshold stored in the data storage unit 10 in advance, it can be specified that the liquid crystal panel 2 under the test has no faults, and the process proceeds to step S19 described below. On the other hand, in a case where the resistance value acquired in step S4 is smaller than or equal to the resistance test threshold stored in the data storage unit 10 in advance, it can be specified that there is a fault between wiring lines in the liquid crystal panel 2 under the test, and the process proceeds to the following step S7.

For example, as illustrated in part (a) of FIG. 5, in a case where a faulty portion 23 exists at a portion where a wiring line X and a wiring line Y intersect each other, an abnormality is detected in the wiring line X4 and the wiring line Y4 in a test of resistance between the wiring lines, and thus the position of the faulty portion 23 can be specified. Thus, in the case of the faulty portion 23 illustrated in part (a) of FIG. 5, it is not always necessary to specify the position thereof through infrared detection (step S6). That is, if a resistance test is performed for each of all the pairs of the wiring lines X and the wiring lines Y, the position can also be specified, and infrared detection is not necessary. However, the number of pairs is enormous, and long time is taken. For example, in the case of a full high-definition liquid crystal panel, the number of wiring lines X is 1080 and the number of wiring lines Y is 1920, and thus the number of all the pairs is about 2.07 million. If a resistance test is performed for each of such pairs, a takt-time becomes long and detection processing ability significantly decreases, which is not practical. The number of resistance tests can be reduced by collectively performing a resistance test by grouping all the pairs of wiring lines X and wiring lines Y into some groups. For example, if a resistance test is performed on a group of the wiring lines X and a group of the wiring lines Y, the number of resistance tests is only one. However, a resistance test enables detection of a short circuit between wiring lines but does not enable specification of the position thereof. Thus, it is necessary to specify the position of the faulty portion 23 through infrared detection.

On the other hand, as in part (b) or (c) of FIG. 5, in a case where a faulty portion 23 is generated between wiring lines adjacent to each other, it can be specified that a faulty portion exists between a pair of wiring lines, for example, between the wiring line X3 and the wiring line X4. However, in the length direction of the wiring lines, the position of the faulty portion 23 cannot be specified, and thus it is necessary to specify the position of the faulty portion 23 through infrared detection.

The number of resistance tests performed between wiring lines adjacent to each other is enormous, which takes long time. For example, in the case of a full high-definition liquid crystal panel, the number of resistance tests performed between wiring lines X adjacent to each other is 1079, and the number of resistance tests performed between wiring lines Y adjacent to each other is 1919. In the case of a resistance test performed between wiring lines X adjacent to each other as in the case of part (b) of FIG. 5, the number of resistance tests is only one if a resistance test is performed between all the odd-numbered wiring lines X and all the even-numbered wiring lines X. In the case of a resistance test performed between wiring lines Y adjacent to each other as in the case of part (c) of FIG. 5, the number of resistance tests is only one if a resistance test is performed between all the odd-numbered wiring lines Y and all the even-numbered wiring lines Y. However, a resistance test enables detection of a short circuit between wiring lines, but does not enable specification of the position thereof. Thus, it is necessary to specify the position of the faulty portion 23 through infrared detection, which is performed from step S7.

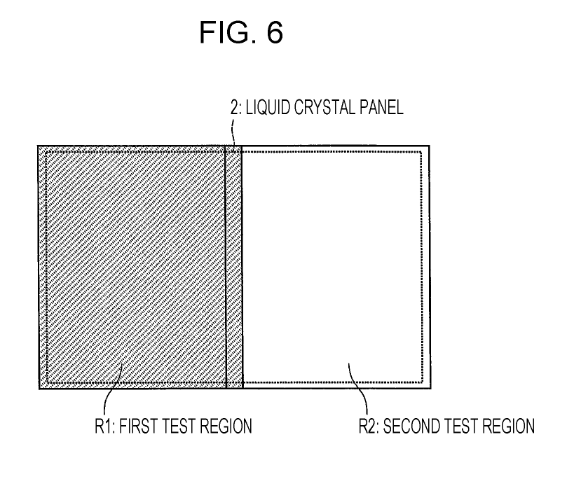

In this embodiment, as illustrated in FIG. 6, one liquid crystal panel 2 is divided into two test regions on the right and left (first test region R1 and second test region R2), and image capturing and fault detection using the infrared camera 5 are performed in the individual test regions. The details are as follows.

In step S7 (storage step), pads which correspond to the individual test regions and to which power is to be supplied are determined in accordance with the size of the liquid crystal panel 2 as a test target and the size of the range of the image capturing field of the infrared camera 5, correspondence data representing correspondence between the individual test regions and the pads is acquired, and the correspondence data is stored in the data storage unit 10 (storage step).

In step S8, the infrared camera 5 is moved to the first test region R1 of the liquid crystal panel 2 using the camera movement means 6 illustrated in FIG. 1.

In step S9, a fault detection mode in which an infrared test is necessary is selected from among the fault detection modes A, B, and C. Specifically, a fault detection mode corresponding to a portion between wiring lines where a fault stored in the data storage unit 10 in step S4 exists is selected.

In step S10, probe pins to be used for supplying power are determined on the basis of the correspondence data stored in step S7, the position of the infrared camera 5 moved in step S8, and the information on the fault detection mode determined in step S9.

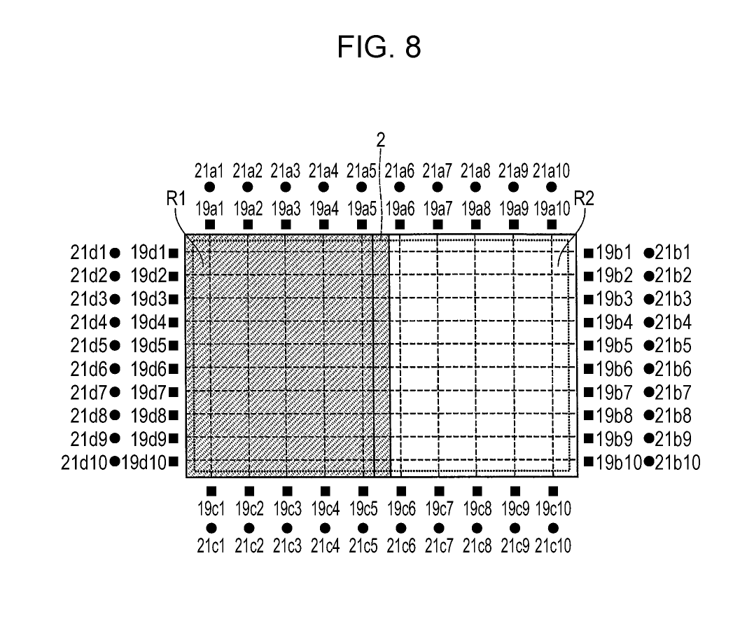

Specifically, in the fault detection mode A, the faulty portions 23 illustrated in part (a) of FIG. 5 can be detected. In a case where the fault detection mode A is selected, the probe pins 21d and part of the probe pins 21a corresponding to the first test region R1 are selected and determined as probe pins for supplying power, among the probe pins 21a to 21d illustrated in part (b) of FIG. 3, so that power is supplied to only the pads 19d on the left and part of the pads 19a on the upper side corresponding to the first test region R1 among the pads 19a to 19d on the upper, lower, right, and left sides illustrated in part (a) of FIG. 3. Specifically, switching to the probe pins 21d and probe pins 21a1 to 21a5 corresponding to pads 19a1 to 19a5 illustrated in FIG. 8 is performed. As a result of applying a voltage (described below) between the individual probe pins 21a1 to 21a5 corresponding to the pads 19a1 to 19a5 and individual probe pins 21d1 to 21d10 corresponding to pads 19d1 to 19d10 illustrated in FIG. 8, heat is generated in the faulty portion 23 corresponding to the fault detection mode A, and the infrared camera 5 becomes capable of capturing an infrared image.

In the fault detection mode B, the faulty portions 23 illustrated in part (b) of FIG. 5 can be detected. In a case where the fault detection mode B is selected, the probe pins 21 are switched to the probe pins 21d among the probe pins 21a to 21d illustrated in part (b) of FIG. 3, so that power is supplied to only the pads 19d among the pads 19a to 19d illustrated in part (a) of FIG. 3. More specifically, a voltage is applied between probe pins 21 (between 21d1 and 21d2, between 21d2 and 21d3, etc.) corresponding to a pair of pads adjacent to each other (for example, a pair of 19d1 and 19d2, a pair of 19d2 and 19d3, etc.) among the pads 19d1 to 19d10 illustrated in FIG. 8. For example, 0 volt may be collectively applied to the probe pins 21d1, 21d3, and 21d5, and 30 volts may be collectively applied to corresponding probe pins 21d2, 21d4, and 21d6. Accordingly, heat is generated in the faulty portion 23 corresponding to the fault detection mode B, and the infrared camera 5 becomes capable of capturing an infrared image.

In the fault detection mode C, the faulty portions 23 illustrated in part (c) of FIG. 5 can be detected. In a case where the fault detection mode C is selected, the probe pins 21 are switched to the probe pins 21a among the probe pins 21a to 21d illustrated in part (b) of FIG. 3, so that power is supplied to only the pads 19a among the pads 19a to 19d illustrated in part (a) of FIG. 3. More specifically, a voltage is applied between probe pins 21 (between 21a1 and 21a2, between 21a2 and 21a3, etc.) corresponding to a pair of pads adjacent to each other (for example, a pair of 19a1 and 19a2, a pair of 19a2 and 19a3, etc.) among the pads 19a1 to 19a5 illustrated in FIG. 8. For example, 0 volt may be collectively applied to the probe pins 21a1, 21a3, and 21a5, and 30 volts may be collectively applied to corresponding probe pins 21a2, 21a4, and 21a6. Accordingly, heat is generated in the faulty portion 23 corresponding to the fault detection mode C, and the infrared camera 5 becomes capable of capturing an infrared image.

In step S11, a voltage value to be applied between wiring lines of the liquid crystal panel 2 is set on the basis of the resistance value stored in the data storage unit 10 in step S4.

Specifically, in step S11, a voltage value of an application voltage V (volt) proportional to the resistance value acquired in step S4 is set.

That is, an application voltage V (volt) is set as expressed by the following equation (1);

[Math. 1]

V=m×R (1),

in which m represents a maximum current value and R represents resistance (ohm),

in step S6 according to this embodiment.

For example, a maximum current value m is specified to be 20 milliamperes, and a voltage value proportional to the resistance is calculated.

Also, a maximum value is set for a voltage value to be calculated (for example, 50 volts). In a case where the set maximum voltage value is larger than the voltage value calculated using equation (1) given above, the maximum voltage value, not the voltage value calculated using equation (1), is set in step S11. Accordingly, a current value of a current flowing between wiring lines of the liquid crystal panel 2 is smaller than the maximum current value.

Here, a current I (ampere) is expressed by the following equation (2);

[Math. 2]

I=V/R=(m×R)/R=m (2).

That is, as a result of appropriately determining an application voltage, a current can be made constant.

Here, the resistance value R of a wiring line formed on the substrate is expressed by the following equation (3);

[Math. 3]

R=ρ×L/A (3),

in which ρ represents electric resistance, L represents wiring length (meter), and A represents cross section area (square meter).

The electric resistance ρ and the cross section area A are constants that are determined by the type and location of a wiring line. Thus, the resistance value R/L=ρ/A of a wiring line per unit length is also a constant. That is, the resistance value r (i) per unit length of the wiring line i is expressed by the following equation (4);

[Math. 4]

r(i)=ρ(i)/A(i)=constant (4),

in which ρ(i) represents the electric resistance of the wiring line i, and A(i) represents the cross section area of the wiring area i,

when it is assumed that the number assigned for each type and location of a wiring line is represented by i.

Here, when it is considered that the amount of heat generation J (joule) per unit time is expressed by the following equation (5);

[Math. 5]

J=W×T=W=V×I=I²×R=V²/R (5),

in which W represents power consumption (watt), T represents time (second), and I represents current (ampere),

the amount of heat generation of the wiring line i per unit length of the wiring line i is expressed by the following equation (6);

[Math. 6]

W(i)=I²×r(i)=m²×r(i)=constant (6),

on the basis of equations (2), (4), and (5) given above.

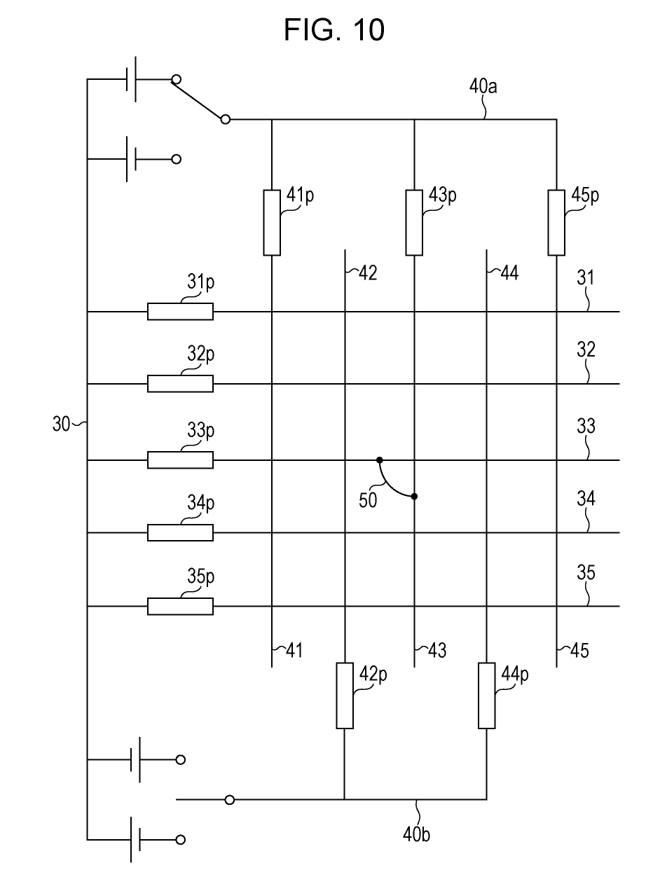

Here, FIG. 10 is a diagram describing a short-circuit path, and is an example of an electric wiring diagram of a thin film transistor substrate. The thin film transistor substrate in FIG. 10 is a substrate in which scanning lines (wiring lines) 31 to 35 and signal lines (wiring lines) 41 to 45 are arranged in a grid pattern on a glass substrate, thin film transistors and transparent pixel electrodes (not illustrated) are connected to individual intersections, and 5×5 pixels are formed in total. This thin film transistor substrate and a common electrode substrate (not illustrated) are placed in parallel with each other, and liquid crystal is sealed therebetween, thereby a liquid crystal panel is formed. Also, on the thin film transistor substrate, as illustrated in FIG. 10, end portions of individual lead lines 31p to 35p of the scanning lines are connected in common by using a common line 30, so as to prevent electrostatic breakdown. The same applies to the signal lines. On the thin film transistor substrate illustrated in FIG. 10, a short-circuit portion 50 is formed between the scanning line 33 and the signal line 43. In such a thin film transistor substrate, in a case where the short-circuit path is divided to the lead line 33p→the scanning line 33→the short-circuit portion 50→the signal line 43→a lead line 43p, the amount of heat generation of the scanning line 33 and the signal line 43 per unit length can be made constant.

Thus, as a result of appropriately setting a constant m in advance regardless of the electric resistance of the short-circuit portion, the scanning line 33 and the signal line 43 can be stably identified using an infrared image.

Also, as a result of further analyzing the identified wiring portion and specifying the portion in which the scanning line 33 and the signal line 43 are short-circuited, the short-circuit portion can be specified. In a case where the resistance value of the short-circuit portion is large, the amount of heat generation in the short-circuit portion is large, and thus the short-circuit portion can be easily specified using an infrared image.

To set a voltage on the basis of the resistance value of a wiring line, the control unit 7 may perform a process of calculating equation (1) given above each time. Alternatively, the relationship between resistance values and voltages may be stored in a table in advance, and the control unit 7 may set a voltage on the basis of a resistance value by referring to the table each time.

That is, the application voltage V (volt) proportional to the resistance value is applied to the liquid crystal panel 2 on the basis of equation (1), and thereby the amount of heat generation per unit time can be made constant.

The resistance value of a short-circuit path including the faulty portions 23 illustrated in FIG. 5 significantly fluctuates due to a short-circuit cause, such as the type of substrate or a location where a fault occurs on the substrate. However, the amount of heat generation per unit time of the short-circuit path including a fault can be made constant by performing step S11. When the amount of heat generation is constant, sufficient heat generation occurs in a fault in a case where the electric resistance value of the fault is large, and sufficient heat generation occurs in a wiring portion of a short-circuit path in a case where the electric resistance value of the fault is small. Therefore, a fault can be easily detected in an infrared test in any case.

In step S12, the voltage expressed by equation (1) and set in step S11 is first applied to the probe pins 21 determined in step S9 (voltage application step). Here, the infrared camera 5 moved in step S8 to the first test region R1 where a fault as a test target exists, is controlled by the control unit 7 so as to be operated in conjunction with the application of the voltage to the probe pins 21. Accordingly, the voltage is applied to the probe pins 21, and heat generation starts in the fault. At the same time, the infrared camera 5 starts capturing an infrared image of the fault. With the use of an infrared image captured before heat is generated in the fault and an infrared image captured after heat is generated in the fault, an infrared test is performed on the basis of the difference image of the infrared images (that is, the difference in temperature between liquid crystal panels before and after voltage application), and a heat generation portion where the temperature exceeds a predetermined temperature difference is determined to be a portion between wiring lines including a fault. With the above-described steps, specification of a heat generation portion using the infrared camera 5a for macro measurement is completed. Subsequently, the infrared camera 5 is switched to the infrared camera 5b for micro measurement, and the infrared camera 5b for micro measurement is moved so as to position a heat generation portion within the field of view of the infrared camera 5b for micro measurement. Accordingly, the coordinate position of the fault can be specified with high accuracy, or measurement for information required for correcting the fault, such as a shape, can be performed. In micro measurement using the infrared camera 5b for micro measurement, the position of not only a line fault but also a point fault can be specified (fault detection step). In this embodiment, the predetermined temperature difference is set to one degree.

In step S13, it is judged whether or not an infrared test has been performed in all the fault detection modes in which an infrared test is necessary. In a case where an infrared test has been performed in all the fault detection modes, the process proceeds to step S14. In a case where an infrared test has not been performed in all the fault detection modes, the process returns to step S9, and the individual steps are repeated.

In step S14, the infrared camera 5 is moved from the first test region R1 to the second test region R2 of the liquid crystal panel 2 using the camera movement means 6 illustrated in FIG. 1.

In step S15, one of the fault detection modes A, B, and C is selected as a fault detection mode to be implemented. Specifically, the fault detection mode corresponding to a portion between wiring lines where a fault stored in the data storage unit 10 in step S4 exists is selected.

In step S16, a voltage value equal to the voltage value set in step S11 is set. That is, the voltage value of the voltage expressed by equation (1) is set.

In step S17, probe pins to be used for supplying power are determined on the basis of the correspondence data stored in step S7, the position of the infrared camera 5 moved in step S14, and the information on the fault detection mode determined in step S15, and switching from the probe pins determined in step S10 is performed using the relay ON/OFF switch.

Specifically, in a case where the fault detection mode A is selected in step S15, the probe pins 21 are switched to part of the probe pins 21b and part of the probe pins 21a corresponding to the second test region R2 among the probe pins 21a to 21d illustrated in part (b) of FIG. 3, so that power is supplied to only the pads 19b and part of the pads 19a corresponding to the second test region R2 among the pads 19a to 19d illustrated in part (a) of FIG. 3. Specifically, switching to individual probe pins 21a6 to 21a10 corresponding to pads 19a6 to 19a10, and individual probe pins 21b1 to 21b10 corresponding to pads 19b1 to 19b10 illustrated in FIG. 8, is performed.

In a case where the fault detection mode B is selected in step S15, the probe pins 21 are switched to the probe pins 21b among the probe pins 21a to 21d illustrated in part (b) of FIG. 3, so that power is supplied to only the pads 19b among the pads 19a to 19d illustrated in part (a) of FIG. 3. Specifically, switching to a pair of probe pins 21 (for example, a pair of 21b1 and 21b2, a pair of 21b2 and 21b3, etc.) corresponding to a pair of pads adjacent to each other (for example, a pair of 19b1 and 19b2, a pair of 19b2 and 19b3, etc.) among the pads 19b1 to 19b10 illustrated in FIG. 8, is performed.

In a case where the fault detection mode C is selected in step S15, the probe pins 21 are switched to the probe pins 21a among the probe pins 21a to 21d illustrated in part (b) of FIG. 3, so that power is supplied to only the pads 19a among the pads 19a to 19d illustrated in part (a) of FIG. 3. Specifically, switching to a pair of probe pins 21 (for example, a pair of 21a6 and 21a7, a pair of 21a7 and 21a8, etc.) corresponding to a pair of pads adjacent to each other (for example, a pair of 19a6 and 19a7, a pair of 19a7 and 19a8, etc.) among the pads 19a6 to 19b10 illustrated in FIG. 8, is performed.

In step S18, the voltage expressed by equation (1) and set in step S15 is first applied to the probe pins 21 switched in step S16 (voltage application step). Here, the infrared camera 5 moved in step S14 to the second test region R2 where a fault as a test target exists, is controlled by the control unit 7 so as to be operated in conjunction with the application of the voltage to the probe pins 21. Accordingly, the voltage is applied to the probe pins 21, and heat generation starts in the fault. At almost the same time, the infrared camera starts capturing an infrared image of the fault. With the use of an infrared image captured before heat is generated in the fault and an infrared image captured after heat is generated in the fault, an infrared test is performed on the basis of the difference image of the infrared images (that is, the difference in temperature between liquid crystal panels before and after voltage application), and a heat generation portion where the temperature exceeds a predetermined temperature difference is determined to be a portion between wiring lines including a fault. With the above-described steps, specification of a heat generation portion using the infrared camera 5a for macro measurement is completed. Subsequently, the infrared camera 5 is switched to the infrared camera 5b for micro measurement, and micro measurement is performed in a manner similar to that described above (fault detection step). In this embodiment, the predetermined temperature difference is set to one degree.

Now, a specific method for applying a voltage will be described with reference to FIGS. 5 and 8.

In a case where the fault detection mode A is selected in step S15, that is, in a case where the faulty portion 23 illustrated in part (a) of FIG. 5 is to be detected, a voltage is applied between the individual probe pins 21a6 to 21a10 corresponding to the pads 19a6 to 19a10 and the individual probe pins 21b1 to 21b10 corresponding to the pads 19b1 to 19b10 illustrated in FIG. 8, and thereby heat is generated in the faulty portion 23 corresponding to the fault detection mode A, and the infrared camera 5 becomes capable of capturing an infrared image.

In a case where the fault detection mode B is selected in step S15, that is, in a case where the faulty portion 23 illustrated in part (b) of FIG. 5 is to be detected, a voltage is applied to a pair of probe pins 21 (a pair of 21d1 and 21d2, a pair of 21d2 and 21d3, etc.) corresponding to a pair of pads adjacent to each other (for example, a pair of 19d1 and 19d2, a pair of 19d2 and 19d3, etc.) among the pads 19d1 to 19d10 illustrated in FIG. 8, and thereby heat is generated in the faulty portion 23 corresponding to the fault detection mode B, and the infrared camera 5 becomes capable of capturing an infrared image.

In a case where the fault detection mode C is selected in step S15, that is, in a case where the faulty portion 23 illustrated in part (c) of FIG. 5 is to be detected, a voltage is applied to a pair of probe pins 21 (a pair of 21a6 and 21a7, a pair of 21a7 and 21a8, etc.) corresponding to a pair of pads adjacent to each other (for example, a pair of 19a6 and 19a7, a pair of 19a7 and 19a8, etc.) among the pads 19a6 to 19a10 illustrated in FIG. 8, and thereby heat is generated in the faulty portion 23 corresponding to the fault detection mode C, and the infrared camera 5 becomes capable of capturing an infrared image.

In step S19, it is judged whether or not an infrared test has been performed in all the fault detection modes in which an infrared test is necessary. In a case where an infrared test has been performed in all the fault detection modes, the process proceeds to step S19. In a case where an infrared test has not been performed in all the fault detection modes, the process returns to step S14, and the individual steps are repeated.

In step S20, it is judged whether or not wiring fault detection has ended in all the 60-inch liquid crystal panels 2 on the mother substrate 1 that is under wiring fault detection. Here, in a case where wiring fault detection has not ended in all the liquid crystal panels 2, the process returns to step S2, the probe is moved to the liquid crystal panel 2 as the next target of wiring fault detection, and wiring fault detection is repeated. On the other hand, in a case where wiring fault detection has ended in all the liquid crystal panels 2, all the steps for wiring fault detection are completed.

As a modification of the wiring fault detection method according to this embodiment, only application of a voltage and capturing of an infrared image may be performed in steps S12 and S18, a new step may be provided just after step S18, and image processing may be performed in the new step on the infrared image captured in step S18.

### (Operation and Effect of First Embodiment)

According to this embodiment, in the configuration in which image capturing is performed twice on the liquid crystal panel 2 that is on a semiconductor substrate (leak fault substrate), is a target of wiring fault detection, and has a range larger than the range of the image capturing field of the infrared camera 5, by changing the relative positions of the infrared camera 5 and the liquid crystal panel 2, heat can be generated by applying a voltage to only each test region of the liquid crystal panel 2 included in the range of the image capturing field of the infrared camera in accordance with change in the relative positions.

Further, since heat is generated by applying a voltage to only each test region of the liquid crystal panel included in the range of the image capturing field of the infrared camera 5 in accordance with change in the relative positions, excessive heat generation of the liquid crystal panel 2 does not occur in the other test regions where an infrared test for wiring fault detection is not performed. That is, in the other test regions where an infrared test for wiring fault detection is not performed, an excessive increase in the temperature of the liquid crystal panel 2 can be prevented. Accordingly, in the case of performing an infrared test for wiring fault detection in the next test region of the liquid crystal panel 2, even if power is immediately supplied to pads 19 of the liquid crystal panel 2 to generate heat in the liquid crystal panel 2, an increase in temperature required to detect a fault can be achieved, and a fault can be appropriately detected.

In this embodiment, the probe 3 suitable for the size of the liquid crystal panel 2 is used. The present invention is not limited thereto, and a different probe may be used in accordance with the position of a test region in the liquid crystal panel and a fault detection mode.

### Second Embodiment

Another embodiment of the wiring fault detection apparatus and wiring fault detection method according to the present invention will be described with reference to FIGS. 1 to 5 and FIG. 9.

### (Configuration of Wiring Fault Detection Apparatus)

The other embodiment of the present invention will be described.

In this embodiment, an apparatus similar to the apparatus according to the first embodiment is used.

In the configuration according to the first embodiment, an infrared test for wiring fault detection is performed on each of two test regions of the liquid crystal panel 2. On the other hand, in this embodiment, a description will be given of an infrared test in a case where the number of divisions of the liquid crystal panel is further increased.

### (Wiring Fault Detection Method)

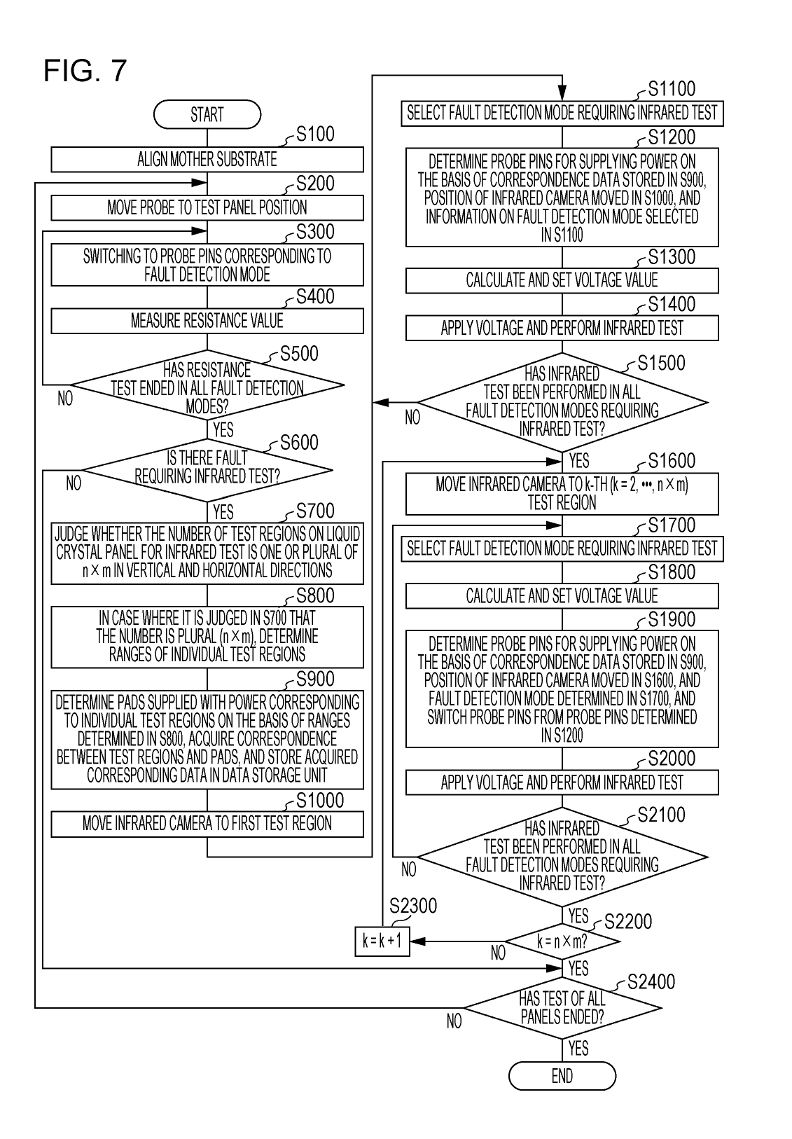

FIG. 7 is a flowchart of a wiring fault detection method using the wiring fault detection apparatus 100 according to this embodiment.

In the first embodiment, for example, a liquid crystal panel of a relatively large size of 60 inches having two test regions is used as the liquid crystal panel 2 on which an infrared test for wiring fault detection is performed. In this embodiment, a large free-size liquid crystal panel 2 is used.

Accordingly, in this embodiment, prior to step S7 described in the first embodiment,

(a) a number-of-test-regions judgment step of judging, with number-of-test-regions judgment means of a control unit, whether or not a liquid crystal panel is to be divided into a plurality of test regions, in accordance with a size of the liquid crystal panel and a range of an image capturing field of an infrared camera, and

(b) a test region determination step of determining, with test region determination means of the control unit, in a case where it is judged in the number-of-test-regions judgment step that the liquid crystal panel is to be divided into a plurality of test regions, a size of each of the test regions are performed.

Hereinafter, the wiring fault detection method according to this embodiment will be described on the basis of steps S100 to S2400.

In step S100, the mother substrate 1 is placed on the alignment stage 11 of the wiring fault detection apparatus 100 illustrated in FIG. 2, and the mother substrate 1 is aligned so as to be parallel with the X and Y coordinate axes.

In step S200, the probe 3 is moved by the probe movement means 4 illustrated in FIG. 2 to a position above a liquid crystal panel 2 as a detection target on the mother substrate 1 that is aligned in step S1, and the probe pins 21a to 21d come into contact with the pads 19a to 19d of the liquid crystal panel 2.

In step S300, after step S200, a portion between wiring lines as a target of a resistance test is selected in accordance with detection modes for various types of fault, and switching of the probe pins 21 to be brought into conduction is performed. Here, the detection modes for various types of fault are the same as the fault detection modes A, B, and C described in the first embodiment.

In step S400, the probe pins 21 switched in step S300 are brought into conduction, and the resistance value between selected wiring lines is measured and acquired. The acquired resistance value is stored in the data storage unit 10, together with information about the selected wiring lines.

In step S500, it is judged whether or not measurement of a resistance value has ended in all the fault detection modes A, B, and C, as in the first embodiment. In a case where measurement in all the fault detection modes has not ended, the process returns to step S300, and the individual steps are repeated. In a case where measurement in all the fault detection modes has ended, the process proceeds to the next step S600.

In step S600, as in the first embodiment, it is judged whether or not there is a fault requiring an infrared test for wiring fault detection in the liquid crystal panel 2 that is under the test. In a case where it is judged that there is not a fault requiring an infrared test, the process proceeds to step S2400 (described below). In a case where it is judged that there is a fault requiring an infrared test, the process proceeds to the following step S700.

In step S700 (number-of-test-regions judgment step), number-of-test-regions judgment means of the control unit judges whether or not the liquid crystal panel is to be divided into a plurality of test regions, in accordance with the size of the liquid crystal panel 2 as a test target and the size of the range of the image capturing field of the infrared camera 5. That is, it is judged whether the number of test regions on the liquid crystal panel 2 when an infrared test is performed is one, or plural of n×m in the vertical and horizontal directions.

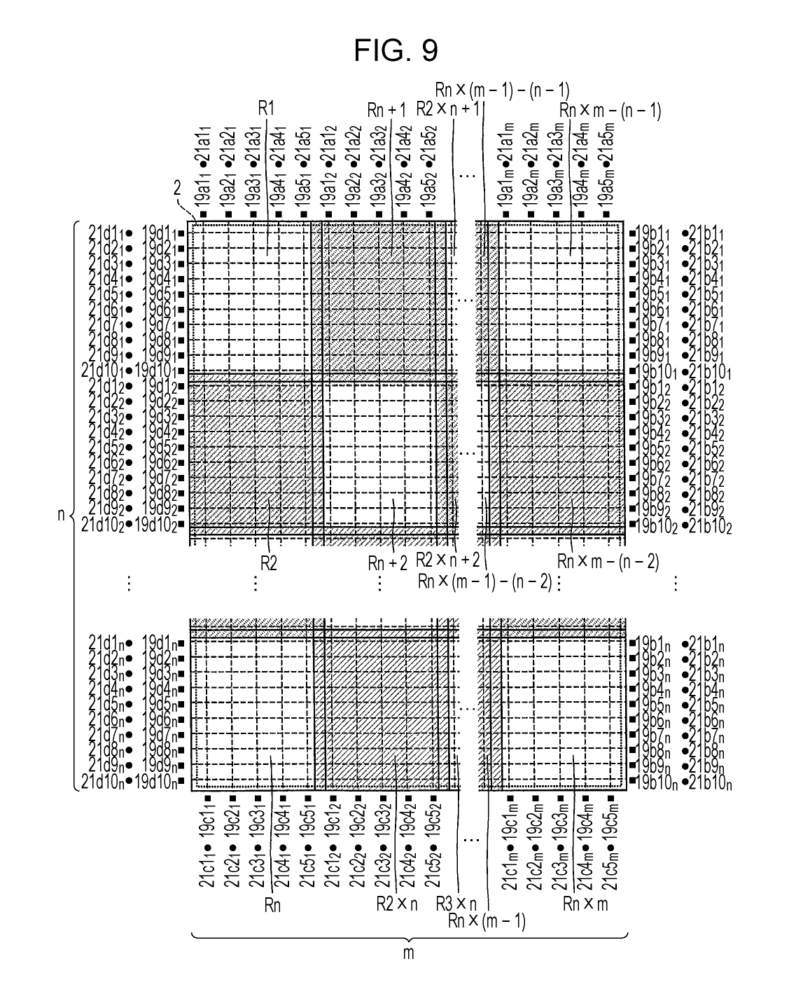

In step S800 (test region determination step), in a case where it is judged in step S700 that the number of test regions on the liquid crystal panel 2 when an infrared test is performed is plural (n×m), test region determination means of the control unit determines the range of each test region in accordance with the size of the liquid crystal panel 2 as a test target and the range of the image capturing field of the infrared camera 5. Here, referring to FIG. 9, the individual test regions of the liquid crystal panel 2 that is divided into n×m test regions in the vertical and horizontal directions include regions R1, R2, . . . , and Rn from the top in the leftmost column, regions Rn+1, Rn+2, . . . , and R2×n from the top in the second column from the left, and regions Rn×m−(n−1), Rn×m−(n−2), and Rn×m from the top in the rightmost column.

In step S900, the pads 19 to which power is to be supplied are determined on the basis of the range of each test region determined in step S800, a correspondence creation unit of the control unit creates correspondence data representing correspondence between the individual test regions R and the pads 19 (correspondence creation step), and the correspondence data is stored in the data storage unit 10 (storage step). Also, the correspondence acquisition unit registers correlation data representing which of the pads 19 on the upper, lower, right, and left sides is to be used in each fault detection mode at each point of two-dimensional distribution (for example, at the interval of 5 cm) in the panel, and stores the correlation data in the data storage unit 10. In a case where a region is automatically divided, the pad to be used is determined on the basis of registration information about the center of the field of view of the infrared camera and the correlation data.

In step S1000, the infrared camera 5 is moved to the first test region R1 of the liquid crystal panel 2 illustrated in FIG. 9 using the camera movement means 6 illustrated in FIG. 1.

In step S1100, a fault detection mode in which an infrared test is necessary is selected from among the fault detection modes A, B, and C. Specifically, a fault detection mode corresponding to a portion between wiring lines where the fault stored in the data storage unit 10 in step S900 exists is selected.

In step S1200, the probe pins to be used for supplying power are determined on the basis of the correspondence data and correlation data stored in step S900, the position of the infrared camera 5 moved in step S1000, and the information on the fault detection mode determined in step S1100.

Specifically, in a case where the fault detection mode A is selected in step S1100, the probe pins 21 are switched to part of the probe pins 21a and part of the probe pins 21d corresponding to the first test region R1 among the probe pins 21a to 21d illustrated in part (b) of FIG. 3, so that power is supplied to only part of the pads 19a and part of the pads 19d corresponding to the first test region R1 among the pads 19a to 19d illustrated in part (a) of FIG. 3. That is, switching to probe pins 21a1₁ to 21a5₁ corresponding to pads 19a1₁ to 19a5₁, and probe pins 21d1₁ to 21d5₁ corresponding to pads 19d1₁ to 19d5₁ illustrated in FIG. 9, is performed.

In a case where the fault detection mode B is selected in step S1100, the probe pins 21 are switched to part of the probe pins 21d corresponding to the first test region R1 among the probe pins 21a to 21d illustrated in part (b) of FIG. 3, so that power is supplied to only part of the pads 19d corresponding to the first test region R1 among the pads 19a to 19d illustrated in part (a) of FIG. 3. That is, switching to probe pins 21d1₁ to 21d10₁ corresponding to pads 19d1₁ to 19d10₁ illustrated in FIG. 9, is performed.

In a case where the fault detection mode C is selected in step S1100, the probe pins 21 are switched to part of the probe pins 21a corresponding to the first test region R1 among the probe pins 21a to 21d illustrated in part (b) of FIG. 3, so that power is supplied to only part of the pads 19a corresponding to the first test region R1 among the pads 19a to 19d illustrated in part (a) of FIG. 3. That is, switching to probe pins 21a1₁ to 21a5₁ corresponding to pads 19a1₁ to 19a5₁ illustrated in FIG. 9, is performed.

In step S1300, a voltage value to be applied between wiring lines of the liquid crystal panel 2 is set on the basis of the resistance value stored in the data storage unit 10 in step S400. A specific method for setting the voltage value is the same as that of the first embodiment.

In step S1400, the voltage expressed by equation (1) and set in step S1300 is first applied to the probe pins 21 determined in step S1200. Here, the infrared camera 5 moved in step S1000 to the first test region R1 where a fault as a test target exists, is controlled by the control unit 7 so as to be operated in conjunction with the application of the voltage to the probe pins 21. Accordingly, the voltage is applied to the probe pins 21, and heat generation starts in the fault. At the same time, the infrared camera 5 starts capturing an infrared image of the fault. With the use of an infrared image captured before heat is generated in the fault and an infrared image captured after heat is generated in the fault, an infrared test is performed on the basis of the difference image of the infrared images (that is, the difference in temperature between liquid crystal panels before and after voltage application), and a heat generation portion where the temperature exceeds a predetermined temperature difference is determined to be a portion between wiring lines including a fault. With the above-described steps, specification of a heat generation portion using the infrared camera 5a for macro measurement is completed. Subsequently, the infrared camera 5 is switched to the infrared camera 5b for micro measurement, and micro measurement similar to that described above is performed (fault detection step). In this embodiment, the predetermined temperature difference is set to one degree.

Now, a specific method for applying a voltage will be described with reference to FIGS. 5 and 9.

In a case where the fault detection mode A is selected in step S1100, that is, in a case where the faulty portion 23 illustrated in part (a) of FIG. 5 is to be detected, a voltage is applied between the individual probe pins 21a1₁ to 21a5₁ corresponding to the pads 19a1₁ to 19a5₁ and the individual probe pins 21d1₁ to 21d10₁ corresponding to the pads 19d1₁ to 19d10₁ illustrated in FIG. 9, and thereby heat is generated in the faulty portion 23 corresponding to the fault detection mode A, and the infrared camera 5 becomes capable of capturing an infrared image.

In a case where the fault detection mode B is selected in step S1100, that is, in a case where the faulty portion 23 illustrated in part (b) of FIG. 5 is to be detected, a voltage is applied between two probe pins adjacent to each other (for example, between 21_{d}1₁ and 21d2₁, between 21_{d}4₁ and 21d5₁, etc.) among the probe pins 21d1₁ to 21d10₁ corresponding to the pads 19d1₁ to 19d10₁ illustrated in FIG. 9, and thereby heat is generated in the faulty portion 23 corresponding to the fault detection mode B, and the infrared camera 5 becomes capable of capturing an infrared image.

In a case where the fault detection mode C is selected in step S1100, that is, in a case where the faulty portion 23 illustrated in part (c) of FIG. 5 is to be detected, a voltage is applied between two probe pins adjacent to each other (for example, between 21a1₁ and 21a2₁, between 21a4₁ and 21a5₁, etc.) among the probe pins 21a1₁ to 21da₁ corresponding to the pads 19a1₁ to 19a5₁ illustrated in FIG. 9, and thereby heat is generated in the faulty portion 23 corresponding to the fault detection mode C, and the infrared camera 5 becomes capable of capturing an infrared image.

In step S1500, it is judged whether or not an infrared test has been performed in all the fault detection modes in which an infrared test is necessary. In a case where an infrared test has been performed in all the fault detection modes, the process proceeds to the next step S1600. In a case where an infrared test has not been performed in all the fault detection modes, the process returns to step S1100, and the individual steps are repeated.

In step S1600, the infrared camera 5 is moved from the first test region R1 of the liquid crystal panel 2 to the k-th test region Rk (k=2, . . . , n×m) located in the q-th row in the vertical direction (1≦q≦n) and the r-th column in the horizontal direction (1≦r≦m), by using the camera movement means 6 illustrated in FIG. 1.

In step S1700, a fault detection mode in which an infrared test is necessary is selected from among the fault detection modes A, B, and C. Specifically, a fault detection mode corresponding to a portion between wiring lines where the fault stored in the data storage unit 10 in step S400 exists is selected.

In step S1800, a voltage value equal to the voltage value set in step S1200 is set. That is, the voltage value of the voltage expressed by equation (1) is set.

In step S1900 (probe pin switching step), the probe pins to be used for supplying power are determined on the basis of the correspondence data and correlation data stored in step S900, the position of the infrared camera 5 moved in step S1600, and information on the fault detection mode selected in step S1700, and switching from the probe pins determined in step S1200 is performed using the relay ON/OFF switch.

Specifically, in a case where the fault detection mode A is selected in step S1700, if the above-mentioned q is n/2 or less and the above-mentioned r is m/2 or less, the probe pins 21 are switched to part of the probe pins 21a and part of the probe pins 21d corresponding to the k-th test region Rk among the probe pins 21a to 21d illustrated in part (b) of FIG. 3, so that power is supplied to only part of the pads 19a and part of the pads 19d corresponding to the k-th test region Rk among the pads 19a to 19d illustrated in part (a) of FIG. 3. That is, switching to probe pins 21a1ᵣ to 21a5ᵣ corresponding to pads 19a1ᵣ to 19a5ᵣ, and probe pins 21d1_{q} to 21d10_{q} corresponding to pads 19d1_{q} to 19d10_{q} illustrated in FIG. 9, is performed. If the above-mentioned q is more than n/2 and the above-mentioned r is more than m/2, the probe pins 21 are switched to part of the probe pins 21c and part of the probe pins 21b corresponding to the k-th test region Rk among the probe pins 21a to 21d illustrated part (b) of FIG. 3, so that power is supplied to only part of the pads 19c and part of the pads 19b corresponding to the k-th test region Rk among the pads 19a to 19d illustrated in part (a) of FIG. 3. That is, switching to probe pins 21c1ᵣ to 21c5ᵣ corresponding to pads 19c1ᵣ to 19c5ᵣ, and probe pins 21b1_{q} to 21b10_{q} corresponding to pads 19b1_{q} to 19b10_{q} illustrated in FIG. 9, is performed. If the above-mentioned q is n/2 or less and the above-mentioned r is more than m/2, the probe pins 21 are switched to part of the probe pins 21a and part of the probe pins 21b corresponding to the k-th test region Rk among the probe pins 21a to 21d illustrated part (b) of FIG. 3, so that power is supplied to only part of the pads 19a and part of the pads 19b corresponding to the k-th test region Rk among the pads 19a to 19d illustrated in part (a) of FIG. 3. That is, switching to probe pins 21a1ᵣ to 21a5ᵣ corresponding to pads 19a1ᵣ to 19a5ᵣ, and probe pins 21b1_{q} to 21b10_{q} corresponding to pads 19b1_{q} to 19b10_{q} illustrated in FIG. 9, is performed. If the above-mentioned q is more than n/2 and the above-mentioned r is m/2 or less, the probe pins 21 are switched to part of the probe pins 21c and part of the probe pins 21d corresponding to the k-th test region Rk among the probe pins 21a to 21d illustrated part (b) of FIG. 3, so that power is supplied to only part of the pads 19c and part of the pads 19d corresponding to the k-th test region Rk among the pads 19a to 19d illustrated in part (a) of FIG. 3. That is, switching to probe pins 21c1ᵣ to 21c5ᵣ corresponding to pads 19c1ᵣ to 19c5ᵣ, and probe pins 21d1_{q} to 21d10_{q} corresponding to pads 19d1_{q} to 19d10_{q} illustrated in FIG. 9, is performed.

Alternatively, instead of using the above-described method in which pads near the test region Rk among the pads on the upper, lower, right, and left sides are used, a method in which pads on the upper side or the lower side are constantly used and pads on the right side or the left side are constantly used may be used, so as to prevent heat generation in a region where a test has not been performed. For example, a method may be used in which power is not supplied to the pads 19c illustrated in part (a) of FIG. 3 and power is constantly supplied to part of the pads 19a corresponding to the k-th test region Rk among the pads 19a illustrated in part (a) of FIG. 3, and power is not supplied to the pads 19b illustrated in part (a) of FIG. 3 and power is constantly supplied to part of the pads 19d corresponding to the k-th test region Rk among the pads 19d illustrated in part (a) of FIG. 3.

In a case where the fault detection mode B is selected in step S1700, if the above-mentioned r is m/2 or less, the probe pins 21 are switched to part of the probe pins 21d corresponding to the k-th test region Rk among the probe pins 21a to 21d illustrated in part (b) of FIG. 3, so that power is supplied to only part of the pads 19d corresponding to the k-th test region Rk among the pads 19a to 19d illustrated in part (a) of FIG. 3. That is, switching to probe pins 21d1_{q} to 21d10_{q} corresponding to pads 19d1_{q} to 19d10_{q} illustrated in FIG. 9, is performed. On the other hand, if the above-mentioned r is more than m/2, the probe pins 21 are switched to part of the probe pins 21b corresponding to the k-th test region Rk among the probe pins 21a to 21d illustrated in part (b) of FIG. 3, so that power is supplied to only part of the pads 19b corresponding to the k-th test region Rk among the pads 19a to 19d illustrated in part (a) of FIG. 3. That is, switching to probe pins 21b1_{q} to 21b10_{q} corresponding to pads 19b1_{q} to 19b10_{q} illustrated in FIG. 9, is performed. In a case where the above-mentioned r is more than m/2, as in a case where r is m/2 or less, the probe pins 21 may be switched to part of the probe pins 21d corresponding to the k-th test region Rk among the probe pins 21a to 21d illustrated in part (b) of FIG. 3, so that power is supplied to only part of the pads 19d corresponding to the k-th test region Rk among the pads 19a to 19d illustrated in part (a) of FIG. 3.

In a case where the fault detection mode C is selected in step S1700, if the above-mentioned q is n/2 or less, the probe pins 21 are switched to part of the probe pins 21a corresponding to the k-th test region Rk among the probe pins 21a to 21d illustrated in part (b) of FIG. 3, so that power is supplied to only part of the pads 19a corresponding to the k-th test region Rk among the pads 19a to 19d illustrated in part (a) of FIG. 3. That is, switching to probe pins 21a1ᵣ to 21a5ᵣ corresponding to pads 19a1ᵣ to 19a5ᵣ illustrated in FIG. 9, is performed. On the other hand, if the above-mentioned q is more than n/2, the probe pins 21 are switched to part of the probe pins 21c corresponding to the k-th test region Rk among the probe pins 21a to 21d illustrated in part (b) of FIG. 3, so that power is supplied to only part of the pads 19c corresponding to the k-th test region Rk among the pads 19a to 19d illustrated in part (a) of FIG. 3. That is, switching to probe pins 21c1ᵣ to 21c5ᵣ corresponding to pads 19c1ᵣ to 19c5ᵣ illustrated in FIG. 9, is performed. In a case where the above-mentioned q is more than n/2, as in a case where q is n/2 or less, the probe pins 21 may be switched to part of the probe pins 21a corresponding to the k-th test region Rk among the probe pins 21a to 21d illustrated in part (b) of FIG. 3, so that power is supplied to only part of the pads 19a corresponding to the k-th test region Rk among the pads 19a to 19d illustrated in part (a) of FIG. 3.

In step S2000, the voltage expressed by equation (1) and set in step S1800 and is applied to the probe pins 21 switched in step S1900. Here, the infrared camera 5 moved in step S1600 to the k-th test region Rk where a fault as a test target exists, is controlled by the control unit 7 so as to be operated in conjunction with the application of the voltage to the probe pins 21. Accordingly, the voltage is applied to the probe pins 21, and heat generation starts in the fault. At the same time, the infrared camera 5 starts capturing an infrared image of the fault. With the use of an infrared image captured before heat is generated in the fault and an infrared image captured after heat is generated in the fault, an infrared test is performed on the basis of the difference image of the infrared images (that is, the difference in temperature between liquid crystal panels before and after voltage application), and a heat generation portion where the temperature exceeds a predetermined temperature difference is determined to be a portion between wiring lines including a fault. With the above-described steps, specification of a heat generation portion using the infrared camera 5a for macro measurement is completed. Subsequently, the infrared camera 5 is switched to the infrared camera 5b for micro measurement, and micro measurement similar to that described above is performed (fault detection step). In this embodiment, the predetermined temperature difference is set to one degree.

Now, a specific method for applying a voltage will be described with reference to FIGS. 5 and 9.

In a case where the fault detection mode A is selected in step S1700, that is, in a case where the faulty portion 23 illustrated in part (a) of FIG. 5 is to be detected, if the above-mentioned q is n/2 or less and the above-mentioned r is m/2 or less, a voltage is applied between the individual probe pins 21a1ᵣ to 21a5ᵣ corresponding to the pads 19a1ᵣ to 19a5ᵣ and the individual probe pins 21d1_{q} to 21d10_{q} corresponding to the pads 19d1_{q} to 19d10_{q} illustrated in FIG. 9, and thereby heat is generated in the faulty portion 23 corresponding to the fault detection mode A, and the infrared camera 5 becomes capable of capturing an infrared image. If the above-mentioned q is more than n/2 and the above-mentioned r is more than m/2, a voltage is applied between the individual probe pins 21c1ᵣ to 21c5ᵣ corresponding to the pads 19c1ᵣ to 19c5ᵣ and the individual probe pins 21b1_{q} to 21b10_{q} corresponding to the pads 19b1_{q} to 19b10_{q} illustrated in FIG. 9, and thereby heat is generated in the faulty portion 23 corresponding to the fault detection mode A, and the infrared camera 5 becomes capable of capturing an infrared image. If the above-mentioned q is n/2 or less and the above-mentioned r is more than m/2, a voltage is applied between the individual probe pins 21a1ᵣ to 21a5ᵣ corresponding to the pads 19a1ᵣ to 19a5ᵣ and the individual probe pins 21d1_{q} to 21d10_{q} corresponding to the pads 19b1_{q} to 19b10_{q} illustrated in FIG. 9, and thereby heat is generated in the faulty portion 23 corresponding to the fault detection mode A, and the infrared camera 5 becomes capable of capturing an infrared image. If the above-mentioned q is more than n/2 and the above-mentioned r is m/2 or less, a voltage is applied between the individual probe pins 21c1ᵣ to 21c5ᵣ corresponding to the pads 19c1ᵣ to 19c5ᵣ and the individual probe pins 21d1_{q} to 21d10_{q} corresponding to the pads 19d1_{q} to 19d10_{q} illustrated in FIG. 9, and thereby heat is generated in the faulty portion 23 corresponding to the fault detection mode A, and the infrared camera 5 becomes capable of capturing an infrared image.

Alternatively, instead of using the above-described method in which a voltage is applied to the probe pins corresponding to the pads near the test region Rk among the pads on the upper, lower, right, and left sides, a method in which pads on the upper side or the lower side are constantly used and pads on the right side or the left side are constantly used, and a voltage is applied to the probe pins corresponding to the pads may be used, so as to prevent heat generation in a region where a test has not been performed. For example, a method may be used in which power is not supplied to the pads 19c illustrated in part (a) of FIG. 3 and power is constantly supplied to part of the pads 19a corresponding to the k-th test region Rk among the pads 19a illustrated in part (a) of FIG. 3, and power is not supplied to the pads 19b illustrated in part (a) of FIG. 3 and power is constantly supplied to part of the pads 19d corresponding to the k-th test region Rk among the pads 19d illustrated in part (a) of FIG. 3.

In a case where the fault detection mode B is selected in step S1700, that is, in a case where the faulty portion 23 illustrated in part (b) of FIG. 5 is to be detected, if the above-mentioned r is m/2 or less, a voltage is applied to a pair of probe pins 21 (a pair of 21d1_{q} and 21d2_{q}, a pair of 21d2_{q} and 21d3_{q}, etc.) corresponding to a pair of pads adjacent to each other (for example, a pair of 19d1_{q} and 19d2_{q}, a pair of 19d2_{q} and 19d3_{q}, etc.) among the pads 19d1_{q} to 19d10_{q} illustrated in FIG. 9, and thereby heat is generated in the faulty portion 23 corresponding to the fault detection mode B, and the infrared camera 5 becomes capable of capturing an infrared image. On the other hand, if the above-mentioned r is more than m/2, a voltage is applied to a pair of probe pins 21 (a pair of 21b1_{q} and 21b2_{q}, a pair of 21b2_{q} and 21b3_{q}, etc.) corresponding to a pair of pads adjacent to each other (for example, a pair of 19b1_{q} and 19b2_{q}, a pair of 19b2_{q} and 19b3_{q}, etc.) among the pads 19b1_{q} to 19b10_{q} illustrated in FIG. 9, and thereby heat is generated in the faulty portion 23 corresponding to the fault detection mode B, and the infrared camera 5 becomes capable of capturing an infrared image. As described above, in a case where r is more than m/2, as in a case where r is m/2 or less, a voltage may be applied to a pair of probe pins 21 (a pair of 21d1_{q} and 21d2_{q}, a pair of 21d2_{q} and 21d3_{q}, etc.) corresponding to a pair of pads adjacent to each other (for example, a pair of 19d1_{q} and 19d2_{q}, a pair of 19d2_{q} and 19d3_{q}, etc.) among the pads 19d1_{q} to 19d10_{q} illustrated in FIG. 9.

In a case where the fault detection mode C is selected in step S1700, that is, in a case where the faulty portion 23 illustrated in part (c) of FIG. 5 is to be detected, if the above-mentioned q is n/2 or less, a voltage is applied to a pair of probe pins 21 (a pair of 21a1ᵣ and 21a2ᵣ, a pair of 21a2ᵣ and 21a3ᵣ, etc.) corresponding to a pair of pads adjacent to each other (for example, a pair of 19a1ᵣ and 19a2ᵣ, a pair of 19a2ᵣ and 19a3ᵣ, etc.) among the pads 19a1ᵣ to 19d5ᵣ illustrated in FIG. 9, and thereby heat is generated in the faulty portion 23 corresponding to the fault detection mode C, and the infrared camera 5 becomes capable of capturing an infrared image. On the other hand, if the above-mentioned q is more than n/2, a voltage is applied to a pair of probe pins 21 (a pair of 21c1ᵣ and 21c2ᵣ, a pair of 21c2ᵣ and 21c3ᵣ, etc.) corresponding to a pair of pads adjacent to each other (for example, a pair of 19c1ᵣ and 19c2ᵣ, a pair of 19c2ᵣ and 19c3ᵣ, etc.) among the pads 19c1ᵣ to 19c5ᵣ illustrated in FIG. 9, and thereby heat is generated in the faulty portion 23 corresponding to the fault detection mode C, and the infrared camera 5 becomes capable of capturing an infrared image.

As described above, in a case where q is more than n/2, as in a case where q is n/2 or less, a voltage may be applied to a pair of probe pins 21 (a pair of 21a1ᵣ and 21a2ᵣ, a pair of 21a2ᵣ and 21a3ᵣ, etc.) corresponding to a pair of pads adjacent to each other (for example, a pair of 19a1ᵣ and 19a2ᵣ, a pair of 19a2ᵣ and 19a3ᵣ, etc.) among the pads 19a1ᵣ to 19d5ᵣ illustrated in FIG. 9.

In step S2100, it is judged whether or not an infrared test has been performed in all the fault detection modes in which an infrared test for wiring fault detection is necessary. In a case where an infrared test has been performed in all the fault detection modes, the process proceeds to the next step S2200. In a case where an infrared test has not been performed in all the fault detection modes, the process returns to the step S1700, and the individual steps are repeated.

In step S2200, it is judged whether or not the test region Rk in which an infrared test for wiring fault detection is currently being performed is the last test region Rn×m. In a case where k=n×m is satisfied, the process proceeds to step S2400. In a case where k=n×m is not satisfied, the process proceeds to step S2300.

In step S2300, k is set to k+1, and the process returns to step S1600, and the individual steps are repeated.

In step S2400, it is judged whether or not wiring fault detection has ended in all the regions of the liquid crystal panel 2 on the mother substrate 1 that is under wiring fault detection. Here, in a case where wiring fault detection has not ended in all the liquid crystal panels 2, the process returns to step S200, in which the probe is moved to the liquid crystal panel 2 as the next target of wiring fault detection, and wiring fault detection is repeated. On the other hand, in a case where wiring fault detection has ended in all the liquid crystal panels 2, all the steps for wiring fault detection are completed.

Here, in the case of sequentially testing n×m test regions in the vertical and horizontal directions, as in this embodiment, it is preferred that the k-th test region Rk be tested in the order of the following regions (A) to (D).

(A) Region where q≦n/2 and r≦m/2

Test is sequentially performed on a vertical column from the top to the bottom, and the vertical column that is tested first is regarded as the leftmost column. After that, test is sequentially performed on the column next to the column from the top to the bottom. After that, test is performed on the next column. In this way, test is performed with the individual columns being scanned in the same direction.

(B) Region where q≦n/2 and r>m/2

Test is sequentially performed on a vertical column from the top to the bottom, and the vertical column that is tested first is regarded as the rightmost column. After that, test is sequentially performed on the column next to the column from the top to the bottom. After that, test is performed on the next column. In this way, test is performed with the individual columns being scanned in the same direction.

(C) Region where q>n/2 and r≦m/2

Test is sequentially performed on a vertical column from the bottom to the top, and the vertical column that is tested first is regarded as the leftmost column. After that, test is sequentially performed on the column next to the column from the top to the bottom. After that, test is performed on the next column. In this way, test is performed with the individual columns being scanned in the same direction.

(D) Region where q>n/2 and r>m/2

Test is sequentially performed on a vertical column from the bottom to the top, and the vertical column that is tested first is regarded as the rightmost column. After that, test is sequentially performed on the column next to the column from the top to the bottom. After that, test is performed on the next column. In this way, test is performed with the individual columns being scanned in the same direction.

In the above-described case, scanning is performed on a vertical column in the vertical direction. Alternatively, scanning may be performed on a horizontal column in the horizontal direction.

In this way, as a result of testing each column by scanning the column in the same direction, heat generation in a region where a test has not been performed can be suppressed as much as possible.

In the case of sequentially testing the n×m test regions in the vertical and horizontal directions as in this embodiment, the following modifications may be implemented as a method for moving a test region.

### (First Modification)

In a first modification, a test may be sequentially performed on a vertical column from the top to the bottom. The vertical column that is tested first is regarded as the leftmost column. After that, test may be sequentially performed on the column next to the column from the top to the bottom. After that, test may be performed on the next column. In this way, test may be performed with the individual columns being scanned in the same direction. In the case of sequentially performing the test in this way, the pads 19a1ᵣ to 19a5ᵣ and 19d1_{q} to 19d10_{q} are selected in the case of the fault detection mode A, the pads 19d1_{q} to 19d10_{q} are selected in the case of the fault detection mode B, and the pads 19a1ᵣ to 19a5ᵣ are selected in the case of the fault detection mode C, as the pads corresponding to the test region Rk.

### (Second Modification)

In a second modification, a test may be sequentially performed on a horizontal column from the left to the right. The horizontal column that is tested first is regarded as the uppermost column. After that, test may be sequentially performed on the column next to the column from the top to the bottom. After that, test may be performed on the next column. In this way, test may be performed with the individual columns being scanned in the same direction. In the case of sequentially performing the test in this way, the pads 19a1ᵣ to 19a5ᵣ and 19d1_{q} to 19d10_{q} are selected in the case of the fault detection mode A, the pads 19d1_{q} to 19d10_{q} are selected in the case of the fault detection mode B, and the pads 19a1ᵣ to 19a5ᵣ are selected in the case of the fault detection mode C, as the pads corresponding to the test region Rk.

### (Operation and Effect of Second Embodiment)

According to this embodiment, in the configuration in which image capturing is performed a plurality of times on the liquid crystal panel 2 that is on a semiconductor substrate (leak fault substrate), is a target of wiring fault detection, and has a range larger than the range of the image capturing field of the infrared camera 5, by changing the relative positions of the infrared camera 5 and the liquid crystal panel 2, heat is generated by applying a voltage to only a test region of the liquid crystal panel 2 included in the range of the image capturing field of the infrared camera in accordance with change in the relative positions.

Since heat is generated by applying a voltage to only a test region of the liquid crystal panel 2 included in the range of the image capturing field of the infrared camera 5 in accordance with change in the relative positions, excessive heat generation of the liquid crystal panel 2 does not occur in the other test regions where an infrared test for wiring fault detection is not performed. That is, in the other test regions where an infrared test for wiring fault detection is not performed, an excessive increase in the temperature of the liquid crystal panel 2 can be prevented. Accordingly, in the case of performing an infrared test for wiring fault detection in the next test region of the liquid crystal panel 2, even if a voltage is immediately applied to pads 19 of the liquid crystal panel 2 to generate heat in the liquid crystal panel 2, an increase in temperature required to detect a fault can be achieved, and a fault can be appropriately detected.

The embodiments of the present invention have been described above, but the present invention is not limited to the above-described embodiments and modifications. The embodiments and modifications can be variously changed within the scope of the claims, and an embodiment achieved by appropriately combining the technical means disclosed in the embodiments is also included in the technical scope of the present invention.

### INDUSTRIAL APPLICABILITY

The present invention can be used for detecting a wiring condition of a semiconductor substrate including wiring lines, such as a liquid crystal panel.

### REFERENCE SIGNS LIST

1 mother substrate (panel)
2 liquid crystal panel (panel)
3 probe (voltage application means)
4 probe movement means
5, 5a, 5b infrared camera
6 camera movement means
7 control unit (pad switching means, correspondence creation unit, number-of-test-regions judgment means, test region determination means, fault detection means)
8 resistance measurement unit
9 voltage application unit (voltage application means)
10 data storage unit
11 alignment stage
12, 16 optical camera
13a, 13b, 13c, 13d, 13e, 13f guide rail
14a, 14b, 14d, 14d mount portion
17 pixel portion
18 peripheral circuit portion
19, 19a, 19b, 19c, 19d pad
21, 21a, 21b, 21c, 21d probe portion
23 faulty portion (wiring short-circuit portion)
30, 40a, 40b common line
31, 32, 33, 34, 35 scanning line
31p, 32p, 33p, 34p, 35p scanning line lead line
41, 42, 43, 44, 45 signal line
41p, 42p, 43p, 44p, 45p signal line lead line
50 short-circuit portion
60 liquid crystal panel
100 wiring fault detection apparatus

1. A wiring fault detection method for detecting a fault of a wiring line by capturing, using an infrared camera, an image of a panel including a plurality of pads and wiring lines, comprising:
a storage step of storing correspondence data in a data storage unit, the correspondence data representing correspondence between a plurality of test regions, which are obtained by dividing the panel in accordance with a region of an image capturing field of the infrared camera, and pads corresponding to the individual test regions among the plurality of pads;
a pad switching step of changing relative positions of the panel and the infrared camera, and switching a pad to which power is to be supplied, on the basis of a position of the region of the image capturing field of the infrared camera and the correspondence data stored in the data storage unit;
a voltage application step of applying, via the pad switched in the pad switching step, a predetermined voltage to the wiring line corresponding to the pad; and
a fault detection step of detecting a fault of the wiring line by capturing, using the infrared camera, an image of a test region including the wiring line to which the voltage is applied in the voltage application step.

2. The wiring fault detection method according to claim 1, wherein a preliminary step of the storage step includes a correspondence creation step of creating the correspondence data by dividing the panel into a plurality of test regions in accordance with the region of the image capturing field of the infrared camera, determining pads corresponding to the individual test regions among the plurality of pads, and associating the test regions with the pads corresponding to the test regions.

3. The wiring fault detection method according to claim 2, wherein a preliminary step of the correspondence creation step includes
a number-of-test-regions judgment step of judging whether or not the panel is to be divided into a plurality of test regions in accordance with a size of the panel and a size of the region of the image capturing field of the infrared camera, and
a test region determination step of determining, in a case where it is judged in the number-of-test-regions judgment step that the panel is to be divided into a plurality of test regions, a size of each of the test regions.

4. The wiring fault detection method according to claim 1, wherein, in the pad switching step, a pad to which power is to be supplied is switched to a pad corresponding to a test region in accordance with the position of the region of the image capturing field of the infrared camera, by switching a probe pin that is to be connected to a corresponding one of the pads to supply power to a probe pin for applying a voltage in the voltage application step.

5. A wiring fault detection apparatus for detecting a fault of a wiring line by capturing, using an infrared camera, an image of a panel including a plurality of pads and wiring lines, comprising:
the infrared camera;
a data storage unit for storing correspondence data, the correspondence data representing correspondence between a plurality of test regions, which are obtained by dividing the panel in accordance with a region of an image capturing field of the infrared camera, and pads corresponding to the individual test regions among the plurality of pads;
movement means for changing relative positions of the panel and the infrared camera;
pad switching means for switching a pad to which power is to be supplied, on the basis of a position of the region of the image capturing field of the infrared camera whose relative position is moved by the movement means, and the correspondence data stored in the data storage unit;
voltage application means for applying, via the pad switched by the pad switching means, a predetermined voltage to the wiring line corresponding to the pad; and
fault detection means for detecting a fault of the wiring line by capturing, using the infrared camera, an image of a test region including the wiring line to which the voltage is applied by the voltage application means,
wherein the pad switching means and the fault detection means are provided in a control unit.

6. The wiring fault detection apparatus according to claim 5, further comprising:
a correspondence creation unit for creating the correspondence data by dividing the panel into a plurality of test regions in accordance with the region of the image capturing field of the infrared camera, determining pads corresponding to the individual test regions among the plurality of pads, and associating the test regions with the pads corresponding to the test regions,
wherein the data storage unit stores the correspondence data created by the correspondence creation unit, and
wherein the correspondence creation unit is provided in the control unit.

7. The wiring fault detection apparatus according to claim 6, wherein the correspondence creation unit includes
number-of-test-regions judgment means for judging whether or not the panel is to be divided into a plurality of test regions in accordance with a size of the panel and a size of the region of the image capturing field of the infrared camera, and
test region determination means for determining, in a case where it is judged by the number-of-test-regions judgment means that the panel is to be divided into a plurality of test regions, a size of each of the test regions.

8. The wiring fault detection apparatus according to claim 5, further comprising:
a probe pin that is to be connected to a corresponding one of the pads to supply power,
wherein the pad switching means switches a pad to which power is to be supplied to a pad corresponding to a test region in accordance with the position of the region of the image capturing field of the infrared camera, by performing switching to the probe pin for applying a voltage using the voltage application means.
